(19) United States
(12) Patent Application Publication
(10) Pub. No.: US 2026/0196980 A1
(43) Pub. Date: Jul. 9, 2026

(54) ACOUSTIC WAVE DEVICE AND COMMUNICATION APPARATUS

(71) Applicant: KYOCERA CORPORATION, Kyoto-shi, Kyoto (JP)

(72) Inventor: Soichiro NOZOE, Kyoto-shi (JP)

(73) Assignee: KYOCERA CORPORATION, Kyoto-shi, Kyoto (JP)

(21) Appl. No.: 18/869,343

(22) PCT Filed: Jun. 1, 2023
(86) PCT No.: PCT/JP2023/020400

§ 371 Date: Nov. 26, 2024

(30) Foreign Application Priority Data
Jun. 1, 2022 (JP) 2022-089625

(51) Int. Cl. H03H 9/25; H03H 9/02; H03H 9/145

(52) U.S. Cl. CPC H03H 9/25; H03H 9/02559; H03H 9/145

(57) ABSTRACT

A miniaturized acoustic wave device is provided. The acoustic wave device includes, a support substrate, a piezoelectric-body layer in direct or indirect contact with the support substrate, and an IDT electrode located on the piezoelectric-body layer. The acoustic wave device excites an asymmetric zero-order mode Lamb wave.

### TECHNICAL FIELD

The present disclosure relates to an acoustic wave device and a communication apparatus.

### BACKGROUND OF INVENTION

A known acoustic wave element has a structure in which an interdigital transducer (IDT) electrode is formed on a piezoelectric crystal. The acoustic wave element can be used as, for example, a filter (SAW filter) that excites a surface acoustic wave (SAW) with a specific frequency or a frequency near the specific frequency and receives an electrical signal with a specific frequency or a frequency near the specific frequency, and is used as a band-pass filter or the like in a communication device (for example, see Patent Document 1).

### CITATION LIST

### Patent Literature

Patent Document 1: JP 2012-257019 A.

### SUMMARY

An acoustic wave device according to an aspect of the present disclosure includes a support substrate, a piezoelectric-body layer, and an IDT electrode. The piezoelectric-body layer is in direct or indirect contact with the support substrate. The IDT electrode is located on the piezoelectric-body layer. The acoustic wave device excites an asymmetric zero-order mode Lamb wave.

### BRIEF DESCRIPTION OF THE DRAWINGS

FIG. 1 is a perspective view of a configuration example of an acoustic wave device according to an embodiment of the present disclosure.

FIG. 2 is a cross-sectional view of a configuration example of an acoustic wave device according to an embodiment of the present disclosure.

FIG. 3 is a schematic diagram illustrating a FEM simulation model of an acoustic wave device.

FIG. 4 is a table showing FEM simulation conditions.

FIG. 5A is a table showing conditions of FEM simulation related to an Al electrode thickness in Study Example 1.

FIG. 5B is a graph showing FEM simulation results of relationship between an Al electrode thickness and a fractional bandwidth Δf in Study Example 1.

FIG. 5C is a graph showing FEM simulation results of relationship between an Al electrode thickness and an acoustic velocity V in Study Example 1.

FIG. 6A is a table showing conditions of FEM simulation related to a LT thickness in Study Example 1.

FIG. 6B is a graph showing FEM simulation results of relationship between a LT thickness and a fractional bandwidth Δf in Study Example 1.

FIG. 6C is a graph showing FEM simulation results of relationship between a LT thickness and an acoustic velocity V in Study Example 1.

FIG. 7A is a table showing conditions of FEM simulation related to a LT cut angle in Study Example 1.

FIG. 7B is a graph showing FEM simulation results of relationship between a LT cut angle and a fractional bandwidth Δf in Study Example 1.

FIG. 7C is a graph showing FEM simulation results of relationship between a LT cut angle and an acoustic velocity V in Study Example 1.

FIG. 8A is a table showing conditions of FEM simulation related to a LT propagation angle in Study Example 1.

FIG. 8B is a graph showing FEM simulation results of relationship between a LT propagation angle and a fractional bandwidth Δf in Study Example 1.

FIG. 8C is a graph showing FEM simulation results of relationship between a LT propagation angle and an acoustic velocity V in Study Example 1.

FIG. 9A is a table showing conditions of FEM simulation related to a Cu electrode thickness in Study Example 2.

FIG. 9B is a graph showing FEM simulation results of relationship between a Cu electrode thickness and a fractional bandwidth Δf in Study Example 2.

FIG. 9C is a graph showing FEM simulation results of relationship between a Cu electrode thickness and an acoustic velocity V in Study Example 2.

FIG. 10A is a table showing conditions of FEM simulation related to a LT thickness in Study Example 2.

FIG. 10B is a graph showing FEM simulation results of relationship between a LT thickness and a fractional bandwidth Δf in Study Example 2.

FIG. 10C is a graph showing FEM simulation results of relationship between a LT thickness and an acoustic velocity V in Study Example 2.

FIG. 11A is a table showing conditions of FEM simulation related to a LT cut angle in Study Example 2.

FIG. 11B is a graph showing FEM simulation results of relationship between a LT cut angle and a fractional bandwidth Δf in Study Example 2.

FIG. 11C is a graph showing FEM simulation results of relationship between a LT cut angle and an acoustic velocity V in Study Example 2.

FIG. 12A is a table showing conditions of FEM simulation related to a LT propagation angle in Study Example 2.

FIG. 12B is a graph showing FEM simulation results of relationship between a LT propagation angle and a fractional bandwidth Δf in Study Example 2.

FIG. 12C is a graph showing FEM simulation results of relationship between a LT propagation angle and an acoustic velocity V in Study Example 2.

FIG. 13A is a table showing conditions of FEM simulation related to a Pt electrode thickness in Study Example 3.

FIG. 13B is a graph showing FEM simulation results of relationship between a Pt electrode thickness and a fractional bandwidth Δf in Study Example 3.

FIG. 13C is a graph showing FEM simulation results of relationship between a Pt electrode thickness and an acoustic velocity V in Study Example 3.

FIG. 14A is a table showing conditions of FEM simulation related to a LT thickness in Study Example 3.

FIG. 14B is a graph showing FEM simulation results of relationship between a LT thickness and a fractional bandwidth Δf in Study Example 3.

FIG. 14C is a graph showing FEM simulation results of relationship between a LT thickness and an acoustic velocity V in Study Example 3.

FIG. 15A is a table showing conditions of FEM simulation related to a LT cut angle in Study Example 3.

FIG. 15B is a graph showing FEM simulation results of relationship between a LT cut angle and a fractional bandwidth Δf in Study Example 3.

FIG. 15C is a graph showing FEM simulation results of relationship between a LT cut angle and an acoustic velocity V in Study Example 3.

FIG. 16A is a table showing conditions of FEM simulation related to a LT propagation angle in Study Example 3.

FIG. 16B is a graph showing FEM simulation results of relationship between a LT propagation angle and a fractional bandwidth Δf in Study Example 3.

FIG. 16C is a graph showing FEM simulation results of relationship between a LT propagation angle and an acoustic velocity V in Study Example 3.

FIG. 17A is a table showing acoustic velocities of a transverse wave in major metal materials.

FIG. 17B shows an equation for calculating an acoustic velocity of a transverse wave.

FIG. 18A is a graph showing relationship between the acoustic velocities of a transverse wave in the electrode materials and center points CP of the electrode thicknesses, based on the results of Study Examples 1 to 3.

FIG. 18B is a graph showing relationship between the acoustic velocities of a transverse wave in the electrode materials and acoustic velocities (acoustic velocities of an elastic wave) V, based on the results of Study Examples 1 to 3.

FIG. 18C is a graph showing relationship between the acoustic velocities of a transverse wave in the electrode materials and fractional bandwidths Δf, based on the results of Study Examples 1 to 3.

FIG. 19A is a table showing conditions of FEM simulation related to an Al electrode thickness in Study Example 5.

FIG. 19B is a graph showing FEM simulation results of relationship between an Al electrode thickness and a fractional bandwidth Δf in Study Example 5.

FIG. 19C is a graph showing FEM simulation results of relationship between an Al electrode thickness and an acoustic velocity V in Study Example 5.

FIG. 20A is a table showing conditions of FEM simulation related to a LN thickness in Study Example 5.

FIG. 20B is a graph showing FEM simulation results of relationship between a LN thickness and a fractional bandwidth Δf in Study Example 5.

FIG. 20C is a graph showing FEM simulation results of relationship between a LN thickness and an acoustic velocity V in Study Example 5.

FIG. 21A is a table showing conditions of FEM simulation related to a LN cut angle in Study Example 5.

FIG. 21B is a graph showing FEM simulation results of relationship between a LN cut angle and a fractional bandwidth Δf in Study Example 5.

FIG. 21C is a graph showing FEM simulation results of relationship between a LN cut angle and an acoustic velocity V in Study Example 5.

FIG. 22A is a table showing conditions of FEM simulation related to a LN propagation angle in Study Example 5.

FIG. 22B is a graph showing FEM simulation results of relationship between a LN propagation angle and a fractional bandwidth Δf in Study Example 5.

FIG. 22C is a graph showing FEM simulation results of relationship between a LN propagation angle and an acoustic velocity V in Study Example 5.

FIG. 23A is a table showing conditions of FEM simulation related to a Cu electrode thickness in Study Example 6.

FIG. 23B is a graph showing FEM simulation results of relationship between a Cu electrode thickness and a fractional bandwidth Δf in Study Example 6.

FIG. 23C is a graph showing FEM simulation results of relationship between a Cu electrode thickness and an acoustic velocity V in Study Example 6.

FIG. 24A is a table showing conditions of FEM simulation related to a LN thickness in Study Example 6.

FIG. 24B is a graph showing FEM simulation results of relationship between a LN thickness and a fractional bandwidth Δf in Study Example 6.

FIG. 24C is a graph showing FEM simulation results of relationship between a LN thickness and an acoustic velocity V in Study Example 6.

FIG. 25A is a table showing conditions of FEM simulation related to a LN cut angle in Study Example 6.

FIG. 25B is a graph showing FEM simulation results of relationship between a LN cut angle and a fractional bandwidth Δf in Study Example 6.

FIG. 25C is a graph showing FEM simulation results of relationship between a LN cut angle and an acoustic velocity V in Study Example 6.

FIG. 26A is a table showing conditions of FEM simulation related to a LN propagation angle in Study Example 6.

FIG. 26B is a graph showing FEM simulation results of relationship between a LN propagation angle and a fractional bandwidth Δf in Study Example 6.

FIG. 26C is a graph showing FEM simulation results of relationship between a LN propagation angle and an acoustic velocity V in Study Example 6.

FIG. 27A is a table showing conditions of FEM simulation related to a Pt electrode thickness in Study Example 7.

FIG. 27B is a graph showing FEM simulation results of relationship between a Pt electrode thickness and a fractional bandwidth Δf in Study Example 7.

FIG. 27C is a graph showing FEM simulation results of relationship between a Pt electrode thickness and an acoustic velocity V in Study Example 7.

FIG. 28A is a table showing conditions of FEM simulation related to a LN thickness in Study Example 7.

FIG. 28B is a graph showing FEM simulation results of relationship between a LN thickness and a fractional bandwidth Δf in Study Example 7.

FIG. 28C is a graph showing FEM simulation results of relationship between a LN thickness and an acoustic velocity V in Study Example 7.

FIG. 29A is a table showing conditions of FEM simulation related to a LN cut angle in Study Example 7.

FIG. 29B is a graph showing FEM simulation results of relationship between a LN cut angle and a fractional bandwidth Δf in Study Example 7.

FIG. 29C is a graph showing FEM simulation results of relationship between a LN cut angle and an acoustic velocity V in Study Example 7.

FIG. 30A is a table showing conditions of FEM simulation related to a LN propagation angle in Study Example 7.

FIG. 30B is a graph showing FEM simulation results of relationship between a LN propagation angle and a fractional bandwidth Δf in Study Example 7.

FIG. 30C is a graph showing FEM simulation results of relationship between a LN propagation angle and an acoustic velocity V in Study Example 7.

FIG. 31A is a graph showing relationship between the acoustic velocities of a transverse wave in the electrode materials and center points CP of the electrode thicknesses, based on the results of Study Examples 5 to 7.

FIG. 31B is a graph showing relationship between the acoustic velocities of a transverse wave in the electrode materials and acoustic velocities (acoustic velocities of an elastic wave) V, based on the results of Study Examples 5 to 7.

FIG. 31C is a graph showing relationship between the acoustic velocities of a transverse wave in the electrode materials and fractional bandwidths Δf, based on the results of Study Examples 5 to 7.

FIG. 32 is a perspective view of another structural example of the acoustic wave device according to the embodiment of the present disclosure.

FIG. 33 is a cross-sectional view of another configuration example of the acoustic wave device according to the embodiment of the present disclosure.

FIG. 34 is a cross-sectional view of another configuration example of the acoustic wave device according to the embodiment of the present disclosure.

FIG. 35 is a diagram illustrating a simplified configuration of a communication apparatus.

### DESCRIPTION OF EMBODIMENTS

An acoustic wave device according to an embodiment as an example of the present disclosure will be described in detail below with reference to drawings. Note that the following description is for better understanding of the gist of the invention and does not limit the present disclosure unless otherwise specified. Unless otherwise specified in the present description, “from A to B” representing a numerical value range means “equal to or greater than A and equal to or less than B”. For convenience of explanation, each of figures, which will be referred to in the following description, is a simplified representation and only includes main members necessary for description of the embodiment. For the sake of brevity, description of known technical matters may be omitted as appropriate. Thus, the acoustic wave device according to the present embodiment may optionally include known constituent members not illustrated in the referenced drawings. The dimensions of the members in each of the drawings do not faithfully represent the actual dimensions of the constituent members, the dimension ratios of the respective members, or the like.

### General Configuration of Acoustic Wave Device

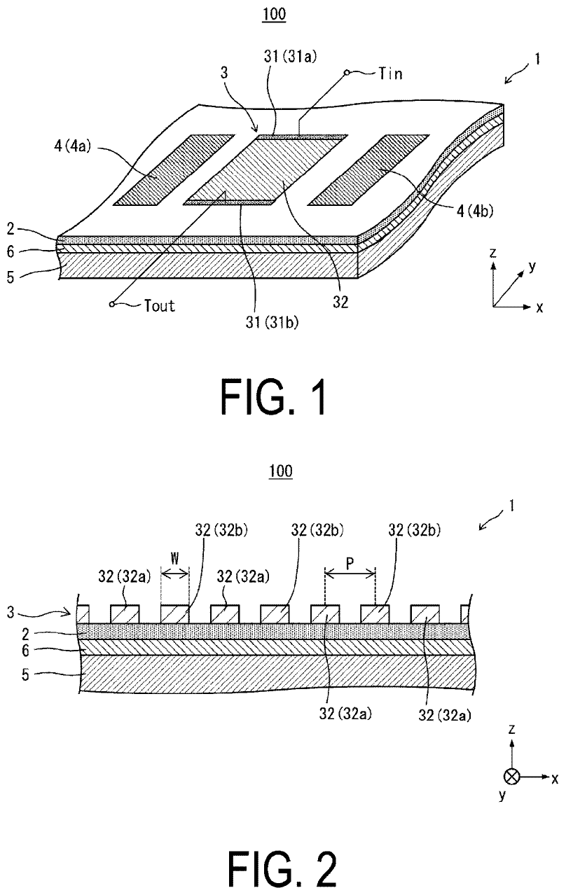

FIG. 1 is a perspective view of a configuration example of an acoustic wave device 100 according to the present embodiment. FIG. 2 is a cross-sectional view of a configuration example of the acoustic wave device 100 according to the present embodiment. The specific shape of an IDT electrode 3 included in the acoustic wave device 100 according to the present embodiment is not particularly limited, and electrode fingers 32 of the IDT electrode 3 may have any of various known shapes. Thus, in FIG. 1, the electrode fingers 32 of the IDT electrode 3 are simply represented by oblique hatching. FIG. 2 and cross-sectional views which will be referred to in the following description are views in which members on the far side of the cross-section are not illustrated (cross-sectional view of a cut portion) for the sake of clarity.

As illustrated in FIGS. 1 and 2, in an aspect of the present disclosure, the acoustic wave device 100 may include at least one resonator 1. In an example of the acoustic wave device 100, the resonator 1 may be connected to an input terminal Tin and an output terminal Tout. The resonator 1 may be configured as a frequency filter (a SAW filter) that filters an electrical signal input to the input terminal Tin and outputs the filtered electrical signal from the output terminal Tout.

The acoustic wave device 100 may include a support substrate 5, a piezoelectric-body layer 2 in direct or indirect contact with the support substrate 5, and an IDT electrode 3 located on the piezoelectric-body layer 2. The IDT electrode 3 is also referred to as an excitation electrode. In the present embodiment, the acoustic wave device 100 is configured to effectively excite an asymmetric zero-order mode Lamb wave. This will be described in detail below.

When the acoustic wave device 100 includes a plurality of resonators 1, the plurality of resonators 1 may be provided on the same support substrate 5 and the same piezoelectric-body layer 2. Each of the plurality of resonators 1 may include an individual IDT electrode 3.

The support substrate 5 supports each part of the acoustic wave device 100. The material for the support substrate 5 is not limited to a specific material, and may be, for example, a Si substrate.

The piezoelectric-body layer 2 may be made of a piezoelectric monocrystal material. For example, the material for the piezoelectric-body layer 2 may be lithium tantalate (LiTaO₃: also referred to as LT) or lithium niobate (LiNbO₃: also referred to as LN).

The acoustic wave device 100 may include an intermediate layer 6 located between the support substrate 5 and the piezoelectric-body layer 2. The support substrate 5 and the piezoelectric-body layer 2 may be bonded to each other via the intermediate layer 6. The constituent material for the intermediate layer 6 may typically be silicon oxide (SiOₓ). In an example, the intermediate layer 6 may be a SiO₂ film. The acoustic wave device 100 may not include the intermediate layer 6. The acoustic wave device 100 including the intermediate layer 6 may be easier to manufacture than the acoustic wave device 100 not including the intermediate layer 6. If the acoustic wave device 100 does not include the intermediate layer 6, the filter characteristics of the acoustic wave device 100 may be adversely affected by a bonding layer between the support substrate 5 and the piezoelectric-body layer 2, which is formed as a result of bonding the support substrate 5 and the piezoelectric-body layer 2 during the manufacturing process of the acoustic wave device 100. This is because the distance between the bonding layer and the surface of the piezoelectric-body layer 2 on the side far from the support substrate 5 is relatively short.

Typically, the IDT electrode 3 is an interdigital electrode including a pair of electrodes consisting of a positive electrode including first electrode fingers 32a, and a negative electrode including second electrode fingers 32b, which are periodically arranged. At a surface of the piezoelectric-body layer 2, the SAW excited by the IDT electrode 3 propagates in a direction orthogonal to the direction in which the first electrode fingers 32a and the second electrode fingers 32b extend.

In the acoustic wave device 100 in FIG. 1, a propagation direction of a SAW propagating in a surface of the piezoelectric-body layer 2 is defined as an x direction, a thickness direction of each member of the acoustic wave device 100 is defined as a z direction, and a direction orthogonal to the x direction and the z direction is defined as a y direction. Hereinafter, the positive direction of the z direction may be referred to as an upward direction, and the negative direction of the z direction may be referred to as a downward direction. The rectangular coordinate system (xyz coordinate system) of FIG. 1 is also shown as appropriate in figures which will be referred to in the following description.

The IDT electrode 3 may include two bus bars 31 (a first bus bar 31a and a second bus bar 31b) facing each other in the y direction. The IDT electrode 3 may include a plurality of first electrode fingers 32a connected to the first bus bar 31a and a plurality of second electrode fingers 32b connected to the second bus bar 31b. The first electrode fingers 32a may extend in the y direction from the first bus bar 31a toward the second bus bar 31b. The second electrode fingers 32b may extend in the y direction from the second bus bar 31b toward the first bus bar 31a.

Referring to FIG. 2, the first electrode fingers 32a and the second electrode fingers 32b may be alternately and repeatedly located on the piezoelectric-body layer 2 at substantially regular intervals in the x direction. The first electrode fingers 32a and the second electrode fingers 32b may collectively referred to herein as the electrode fingers 32. The electrode finger pitch (pitch between electrode fingers) p in the IDT electrode 3 may be the distance between the centers of two adjacent electrode fingers 32 in the x direction (in other words, the repetition interval of the electrode fingers 32). In general, the wavelength λ of the SAW excited by the IDT electrode 3 may be defined as a length twice as long as the electrode finger pitch p. In the following, the definition λ=2 p is used.

The length of one of the electrode fingers 32 (the first electrode fingers 32a or the second electrode fingers 32b) in the x direction is referred to herein as a width w. The first electrode fingers 32a and the second electrode fingers 32b may have the same or substantially the same widths w. As used herein, “substantially the same” means substantially the same, and means that a dimensional difference (error) within about ±5% is acceptable. The same applies to the following description, and repeated description is omitted.

The width w may be set appropriately according to the electric characteristics required for the acoustic wave device 100, for example. In an example, the width w may be set according to the electrode finger pitch p. The ratio of the width w to the electrode finger pitch p (w/p) is referred to herein as a Duty. In the resonator 1, the width w and the electrode finger pitch p may be constant (that is, the duty may be constant) across all the electrode fingers 32. “Constant” is used herein to mean that an error within about ±5 degrees is acceptable, rather than to exactly mean that no change occurs.

The electrode fingers 32 may be made of, for example, a metal material and have a thin flat plate shape extending in the y direction. Examples of the metal may include aluminum (Al), copper (Cu), and platinum (Pt). The configuration (material and thickness) of the electrode fingers 32 will be described in more detail later.

The IDT electrode 3 may further include a protective layer covering the electrode fingers 32. The material for the protective layer may be, for example, SiO₂, and an insulating material commonly used for a protective layer may be used as appropriate.

The acoustic wave device 100 may include a pair of reflectors 4a and 4b corresponding to the IDT electrode 3. The reflectors 4a and 4b are also collectively referred herein to as reflectors 4. The IDT electrode 3 may be located between the reflectors 4 in the x direction.

### Summary of Findings of Present Disclosure

Communication devices or the like utilize, for communication, relatively low frequency band, for example, from 700 MHz to 900 MHz (hereinafter, may be referred to as a “target frequency band” for convenience of description). A value calculated by dividing the bandwidth (pass-band width) by the center frequency (resonance frequency) is called a fractional bandwidth (which may be referred to herein as a “fractional bandwidth Δf”). Of fractional bandwidths Δf of the current communication bands using the target frequency band, the least fractional bandwidth Δf is 1.1% for the downstream communication in Band 6. The present inventors set, as requirements in filter characteristics to be satisfied by the acoustic wave device 100, a goal of achieving a bandwidth in the target frequency band and a fractional bandwidth Δf of 1.1% or more.

The acoustic wave device 100 to be mounted on a communication device or the like that uses the target frequency band needs to further be miniaturized. A Lamb wave having a vibration plane perpendicular to the surface of the piezoelectric-body layer 2 is generally known as one of various propagation modes of SAW and is known to be multi-modal. Among the Lamb waves, an asymmetric zero-order mode Lamb wave (also referred to as an “A0 mode Lamb wave”) has a lower acoustic velocity than various general SAWs. As used herein, “acoustic velocity” means a propagation velocity of an elastic wave used in the acoustic wave device 100, and may also be referred to as a phase velocity.

The present inventors have conceived the idea of using the A0 mode Lamb wave to reduce the acoustic velocity V to achieve a reduction in the size of the acoustic wave device 100. The thinner the piezoelectric-body layer 2 is, the lower the acoustic velocity V of the A0 mode Lamb wave becomes. However, an acoustic wave device 100 that uses an A0 mode Lamb wave and satisfies the requirement that the fractional bandwidth Δf in the target frequency band is equal to or greater than 1.1% is not known, and specific conditions required for the acoustic wave device 100 are not clear.

The present inventors evaluated, by using a finite element method (FEM) simulation, relationships between specific structures and filter characteristics of the acoustic wave devices 100 having the above-described basic structure (bonded structure). As a result, the present inventors have found conditions defined for the structure of the acoustic wave device 100, and have made the present invention. Hereinafter, the result of research by the present inventors using the FEM simulation, i.e., a structure of the resonator 1 in the acoustic wave device 100 which has the fractional bandwidth Δf and the acoustic velocity V characteristics satisfying predetermined requirements will be described.

### Basic Structure of FEM Simulation

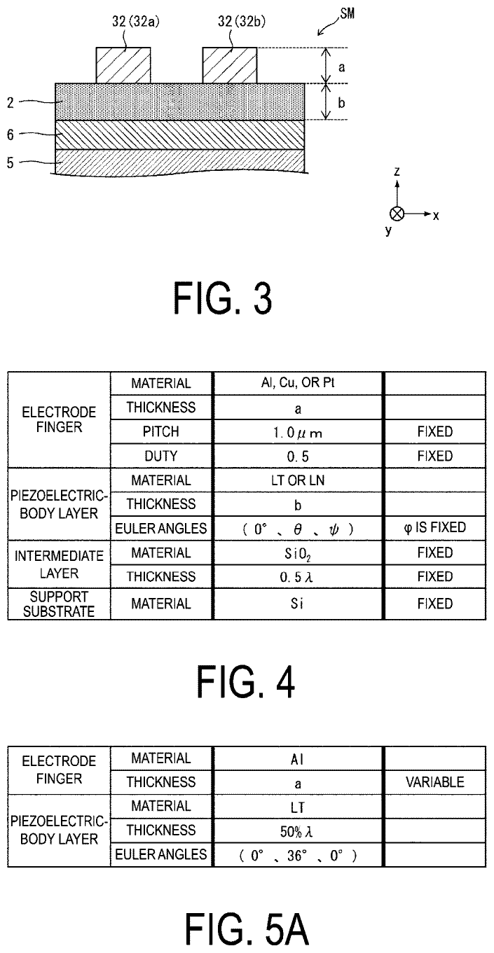

FIG. 3 is a schematic diagram illustrating a FEM simulation model of an acoustic wave device. FIG. 4 is a table showing FEM simulation conditions. As illustrated in FIG. 3, in a FEM simulation model SM of an acoustic wave device, the piezoelectric-body layer 2 is bonded above the support substrate 5 with the intermediate layer 6 interposed therebetween, and the first electrode fingers 32a and the second electrode fingers 32b are located on a surface of the piezoelectric-body layer 2.

The FEM simulation was performed under the conditions shown in FIG. 4. The material for the electrode fingers 32 was Al, Cu, or Pt. The material for the piezoelectric-body layer 2 was LT (LiTaO₃) or LN (LiNbO₃). The thickness of the electrode fingers 32, and the thickness, cut angle, and propagation angle of the piezoelectric-body layer 2 were variables. In the FEM simulation, the electrode finger pitch p was fixed to 1.0 μm and the duty was fixed to 0.5. The wavelength λ of the asymmetric zero-order mode Lamb wave was 2.0 μm which is a length twice as long as the electrode finger pitch p.

In a preliminary FEM simulation, the thickness of the intermediate layer 6 did not significantly affect the filter characteristics. Thus, in the FEM simulations described below, the material for the intermediate layer 6 was SiO₂, and the thickness of the intermediate layer 6 was fixed to 0.5λ as a general value.

The Euler angles of the piezoelectric-body layer 2 can be generally represented by (φ, θ, ψ). In the FEM simulations described below, φ was fixed at 0°, and θ and ψ were variables. The meaning of each of Euler angles φ, θ, and ψ of the piezoelectric-body layer 2 can be understood based on common technical knowledge. For the sake of brevity, a detailed description of the Euler angles of the piezoelectric-body layer 2 is omitted.

For each of a plurality of FEM simulation results described below, a condition range within which each variable needs to be fallen and a center point CP within the range were identified. As used herein, the “center point CP” does not mean a median value of the range but a value selected in consideration of a balance between characteristics of the fractional bandwidth Δf and the acoustic velocity V, and the reason why the value was selected will be described later for each FEM simulation result.

### Study Example 1: LT Film/Al Electrode

In Study Example 1, FEM simulations in which the electrode material was Al and the piezoelectric-body layer 2 was a LT film were performed.

### Al Electrode Thickness

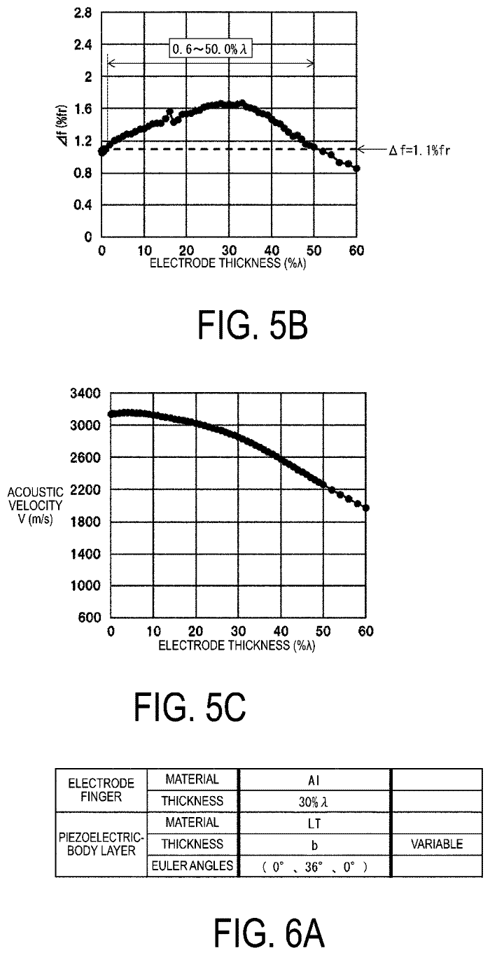

FIG. 5A is a table showing conditions of FEM simulation related to an Al electrode thickness in Study Example 1. FIG. 5B is a graph showing FEM simulation results of relationship between an Al electrode thickness and a fractional bandwidth Δf in Study Example 1. FIG. 5C is a graph showing FEM simulation results of relationship between an Al electrode thickness and an acoustic velocity V in Study Example 1. In the FEM simulation regarding the Al electrode thickness in Study Example 1, the Euler angles of the piezoelectric-body layer 2 were fixed to general values (0 °, 36°, 0°). The LT thickness was fixed at 50% λ.

As shown in FIGS. 5A to 5C, it can be seen that the fractional bandwidth Δf was 1.1% fr or more, when the Al electrode thickness was in a range from 0.6% λ to 50.0% λ. As for the relationship between the acoustic velocity V and the Al electrode thickness, it can be seen that the acoustic velocity V generally tends to decrease with increasing Al electrode thickness. The local maximum point in a fitted curve of the plot of the fractional bandwidth Δf shown in FIG. 5B was selected as the center point CP. Thus, the center point CP of the Al electrode thickness in Study Example 1 was 30% λ.

“% fr” may be used herein as the unit of the fractional bandwidth Δf. This means a percentage expression of a value calculated by dividing the pass-band width by the resonance frequency (fr).

### LT Thickness

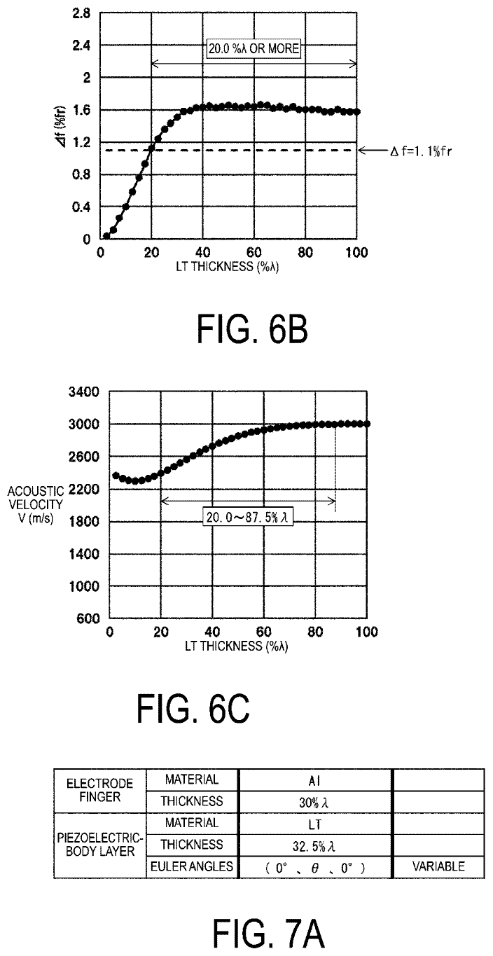

FIG. 6A is a table showing conditions of FEM simulation related to a LT thickness in Study Example 1. FIG. 6B is a graph showing FEM simulation results of relationship between a LT thickness and a fractional bandwidth Δf in Study Example 1. FIG. 6C is a graph showing FEM simulation results of relationship between a LT thickness and an acoustic velocity V in Study Example 1. In the FEM simulation regarding the LT thickness in Study Example 1, the Euler angles of the piezoelectric-body layer 2 were fixed to general values (0°, 36°, 0°), and the Al electrode thickness was fixed to 30% λ, which is the center point CP in the above-described FEM simulation result.

As shown in FIGS. 6A to 6C, it can be seen that the fractional bandwidth Δf was 1.1% fr or more, when the LT Thickness was in a range of 20.0% λ or more. When the LT thickness was in a range of 20.0% λ or more, the acoustic velocity V increased with increasing the LT thickness, and the acoustic velocity V reached a saturated value when the LT thickness was 87.5% λ. Based on this result, a point at which the fractional bandwidth Δf was relatively large and the acoustic velocity B was relatively low was selected as the center point CP. Thus, the center point CP of the LT thickness in Study Example 1 was 32.5% λ.

### LT Cut Angle

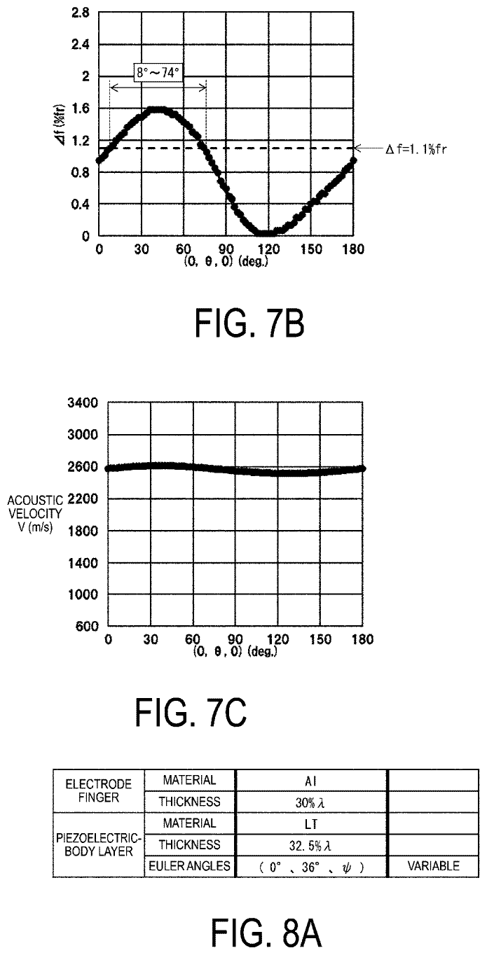

FIG. 7A is a table showing conditions of FEM simulation related to a LT cut angle in Study Example 1. FIG. 7B is a graph showing FEM simulation results of relationship between a LT cut angle and a fractional bandwidth Δf in Study Example 1. FIG. 7C is a graph showing FEM simulation results of relationship between a LT cut angle and an acoustic velocity V in Study Example 1. In the FEM simulation regarding the LT cut angle in Study Example 1, the Al electrode thickness was fixed to 30% λ, which is the center point CP in the above-described FEM simulation result, and the LT thickness was fixed to 32.5% λ, which is the center point CP in the above-described FEM simulation result.

As shown in FIGS. 7A to 7C, it can be seen that the fractional bandwidth Δf was 1.1% fr or more, when the LT cut angle was in a range from 8° to 74°. For the sake of consistency with searches in other FEM simulation, the center point CP of the LT cut angle was set to 36°. As shown in FIG. 7B, it can be seen that the center point CP of the LT cut angle is located near the local maximum point in the fitted curve of the plot of the fractional bandwidth Δf.

### LT Propagation Angle

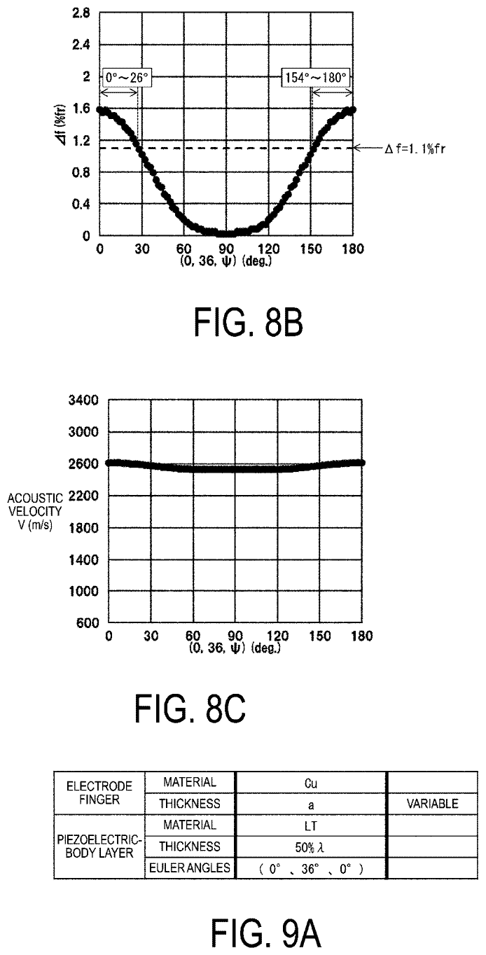

FIG. 8A is a table showing conditions of FEM simulation related to a LT propagation angle in Study Example 1. FIG. 8B is a graph showing FEM simulation results of relationship between a LT propagation angle and a fractional bandwidth Δf in Study Example 1. FIG. 8C is a graph showing FEM simulation results of relationship between a LT propagation angle and an acoustic velocity V in Study Example 1. In the FEM simulation regarding the LT propagation angle in Study Example 1, the Al electrode thickness was fixed to 30% λ, which is the center point CP in the above-described FEM simulation result. The LT thickness was fixed to 32.5% λ, which is the center point CP in the above-described FEM simulation result, and the LT cut angle was fixed to 36°.

As shown in FIGS. 8A to 8C, it can be seen that the fractional bandwidth Δf was 1.1% fr or more, when the LT propagation angle was in a range from 0° to 26° or a range from 154° to 180°, in other words, when the LT propagation angle was in a range from −26° to 26°. Since the LT propagation angles of 0° and 180° are equivalent to each other, the fitted curve of the plot of the fractional bandwidth Δf shown in FIG. 8B actually has an upwardly convex peak. The local maximum point in the fitted curve was selected as the center point CP. That is, the center point CP of the LT propagation angle was 0°.

### First Configuration Example

In the acoustic wave device 100 according to a first configuration example of the present embodiment based on the FEM simulation results of Study Example 1 described above, the piezoelectric-body layer 2 includes lithium tantalate (LT) as a main component of the constituent material thereof and has a thickness ranging from 20.0% λ to 87.5% λ. The piezoelectric-body layer 2 has Euler angles (φ, θ, ψ), where φ is in a range from −5° to 5°, θ is in a range from 8° to 74°, and ψ is in a range from −26° to 26°. The IDT electrode 3 includes Al as a main component of the constituent material thereof and has a thickness ranging from 0.6% λ to 50.0% λ. λ is the wavelength λ of an A0 mode Lamb wave and is defined as a length twice as long as the pitch p of the plurality of electrode fingers 32 included in the IDT electrode 3. This definition of λ will be also used hereinafter in the present description, and thus will not be repeated.

The range from −5° to 5° for φ in the Euler angles of the piezoelectric-body layer 2 is defined as tolerance in manufacturing process. Variation of φ within the range from −5° to 5° does not substantially affect the characteristics of the acoustic wave device 100.

In the acoustic wave device 100 according to the first configuration example, the resonator 1 can effectively excite or receive the A0 mode Lamb wave. The acoustic wave device 100 according to the first configuration example functions as a SAW filter using the A0 mode Lamb wave, and has frequency characteristics including the fractional bandwidth Δf of 1.1% fr or more.

The acoustic velocities V of the known SAWs are about 4000 m/s, and the acoustic velocity V of the A0 mode Lamb wave is slower than those of the known SAWs. For example, based on comparison between the acoustic wave device 100 having a certain resonance frequency and an acoustic wave device (a known acoustic wave device) using a known SAW and having the same resonance frequency, the following can be said. According to the fact that the acoustic velocity V of the A0 mode Lamb wave is lower than those of the known SAWs, and according to V=fλ (where f is constant) and λ=2p, a smaller electrode finger pitch p can be used in the acoustic wave device 100 than in the known acoustic wave device. For example, when the resonance frequency fr is 1000 MHz, V=4000 m/s results in the electrode finger pitch p of 2 μm, and V=2000 m/s results in the electrode finger pitch p of 1 μm. Assuming that the total number of the electrode fingers 32 is the same, using a smaller electrode finger pitch p makes it possible to provide more compact IDT electrode 3.

In the acoustic wave device 100 of the first configuration example, the A0 mode Lamb wave propagating at the acoustic velocity V lower than those of the known SAWs is used, and thus the resonator 1 can be miniaturized. As a result, the acoustic wave device 100 having frequency characteristics including the fractional bandwidth Δf of 1.1% fr or more can be effectively miniaturized.

### Supplementary Note

In the present embodiment, “includes a component A as a main component of a constituent material” means that the proportion of the component A relative to the total amount of constituent material is greater than 50 mass %. This definition will be also used hereinafter in the present description, and thus will not be repeated.

In the acoustic wave device 100 according to the first configuration example of the present embodiment, the piezoelectric-body layer 2 may be made of LT or substantially made of LT. The IDT electrode 3 may be made of Al or may be substantially made of Al. In the present embodiment, “substantially made of a component B” means that the proportion of the component B relative to the total amount of constituent materials is equal to or greater than 90 mass %. This definition will be also used hereinafter in the present description, and thus will not be repeated.

Without being limited to the above examples, in the acoustic wave device 100 according to the first configuration example of the present embodiment, the piezoelectric-body layer 2 may include LT in an amount of 70 mass % or more, or 80 mass % or more. The piezoelectric-body layer 2 may include, as constituent materials other than LT, an optional additive component and inevitable impurities.

In the acoustic wave device 100 according to the first configuration example of the present embodiment, the IDT electrode 3 may include Al in an amount of 70 mass % or more, or 80 mass % or more. The IDT electrode 3 may include, as constituent materials other than Al, an optional additive component and inevitable impurities.

### Study Example 2: LT Film/Cu Electrode

In Study Example 2, FEM simulations in which the electrode material was Cu and the piezoelectric-body layer 2 was a LT film were performed.

### Cu Electrode Thickness

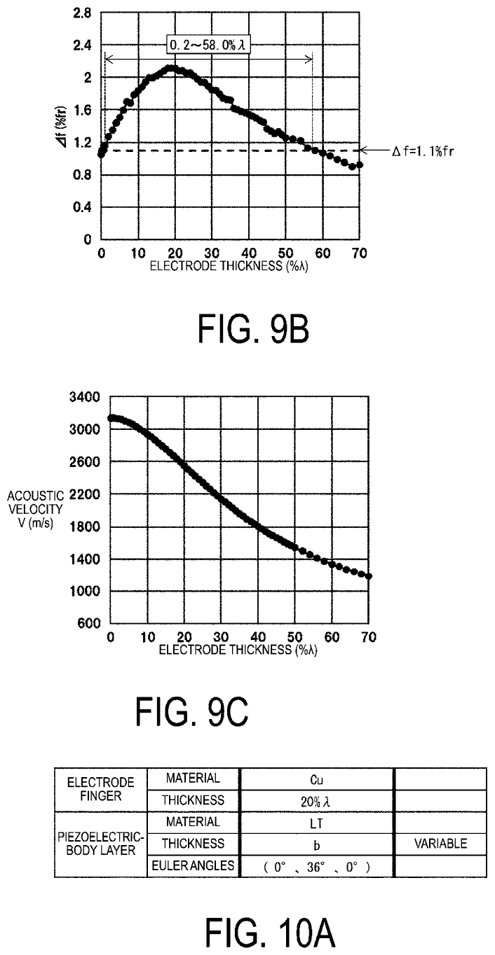

FIG. 9A is a table showing conditions of FEM simulation related to a Cu electrode thickness in Study Example 2. FIG. 9B is a graph showing FEM simulation results of relationship between a Cu electrode thickness and a fractional bandwidth Δf in Study Example 2. FIG. 9C is a graph showing FEM simulation results of relationship between a Cu electrode thickness and an acoustic velocity V in Study Example 2. In the FEM simulation regarding the Cu electrode thickness in Study Example 2, the Euler angles of the piezoelectric-body layer 2 were fixed to general values (0°, 36°, 0°).

As shown in FIGS. 9A to 9C, it can be seen that the fractional bandwidth Δf was 1.1% fr or more, when the Cu electrode thickness was in a range from 0.2%λ to 50.0% λ. As for the relationship between the acoustic velocity V and the Cu electrode thickness, it can be seen that the acoustic velocity V generally tends to decrease with increasing Cu electrode thickness. The local maximum point in a fitted curve of the plot of the fractional bandwidth Δf shown in FIG. 9B was selected as the center point CP. Thus, the center point CP of the Cu electrode thickness in Study Example 2 was 20% λ.

### LT Thickness

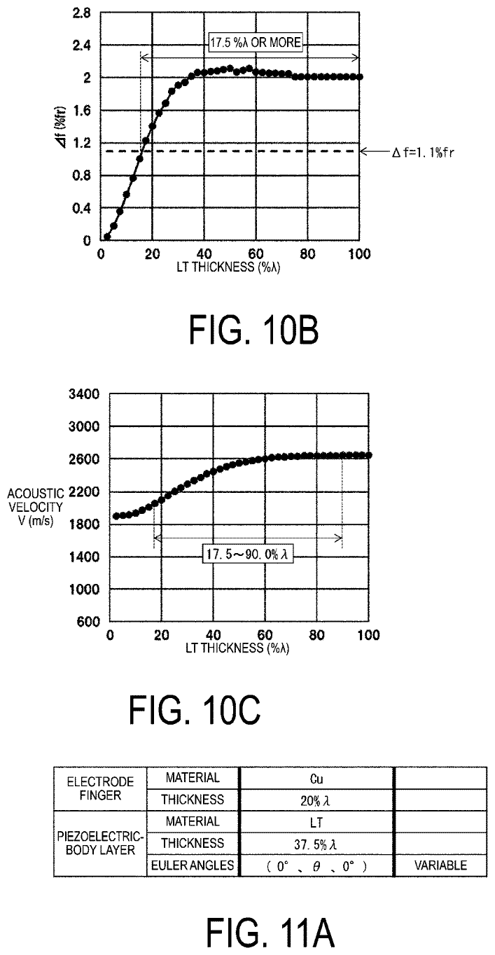

FIG. 10A is a table showing conditions of FEM simulation related to a LT thickness in Study Example 2. FIG. 10B is a graph showing FEM simulation results of relationship between a LT thickness and a fractional bandwidth Δf in Study Example 2. FIG. 10C is a graph showing FEM simulation results of relationship between a LT thickness and an acoustic velocity V in Study Example 2. In the FEM simulation regarding the LT thickness in Study Example 2, the Euler angles of the piezoelectric-body layer 2 were fixed to general values (0°, 36°, 0°), and the Cu electrode thickness was fixed to 20% λ, which is the center point CP in the above-described FEM simulation result.

As shown in FIGS. 10A to 10C, it can be seen that the fractional bandwidth Δf was 1.1% fr or more, when the LT Thickness was in a range of 17.5% λ or more. When the LT thickness was in a range of 17.5% λ or more, the acoustic velocity V increased with increasing the LT thickness, and the acoustic velocity V reached a saturated value when the LT thickness was 90.0% λ. Based on this result, a point at which the fractional bandwidth Δf was relatively large and the acoustic velocity B was relatively low was selected as the center point CP. Thus, the center point CP of the LT thickness in Study Example 2 was 37.5% λ.

### LT Cut Angle

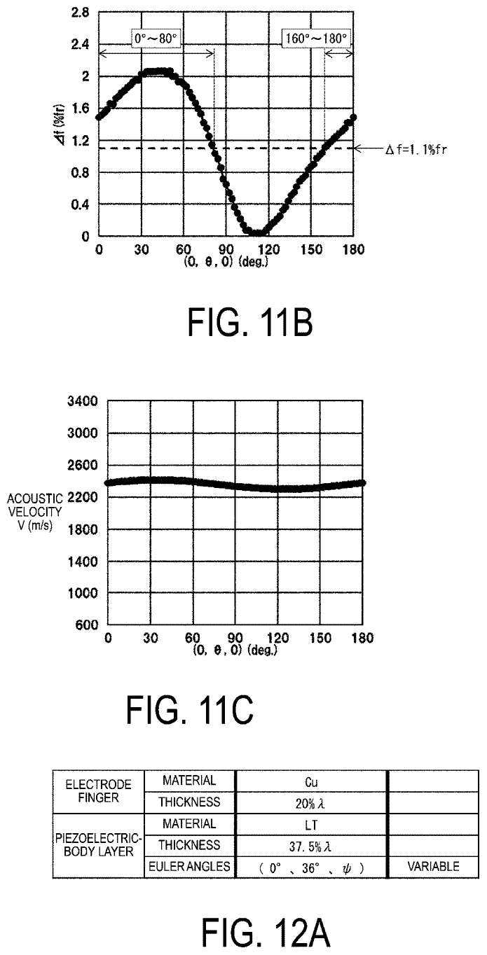

FIG. 11A is a table showing conditions of FEM simulation related to a LT cut angle in Study Example 2. FIG. 11B is a graph showing FEM simulation results of relationship between a LT cut angle and a fractional bandwidth Δf in Study Example 2. FIG. 11C is a graph showing FEM simulation results of relationship between a LT cut angle and an acoustic velocity V in Study Example 2. In the FEM simulation regarding the LT cut angle in Study Example 2, the Cu electrode thickness was fixed to 20% λ, which is the center point CP in the above-described FEM simulation result, and the LT thickness was fixed to 37.5% λ, which is the center point CP in the above-described FEM simulation result.

As shown in FIGS. 11A to 11C, it can be seen that the fractional bandwidth Δf was 1.1% fr or more, when the LT cut angle was in a range from 0° to 80° or a range from 160° to 180°, in other words, when the LT cut angle was in a range from −20° to 80°. For the sake of consistency with searches in other FEM simulation, the center point CP of the LT cut angle was set to 36°. As shown in FIG. 11B, it can be seen that the center point CP of the LT cut angle is located near the local maximum point in the fitted curve of the plot of the fractional bandwidth Δf.

### LT Propagation Angle

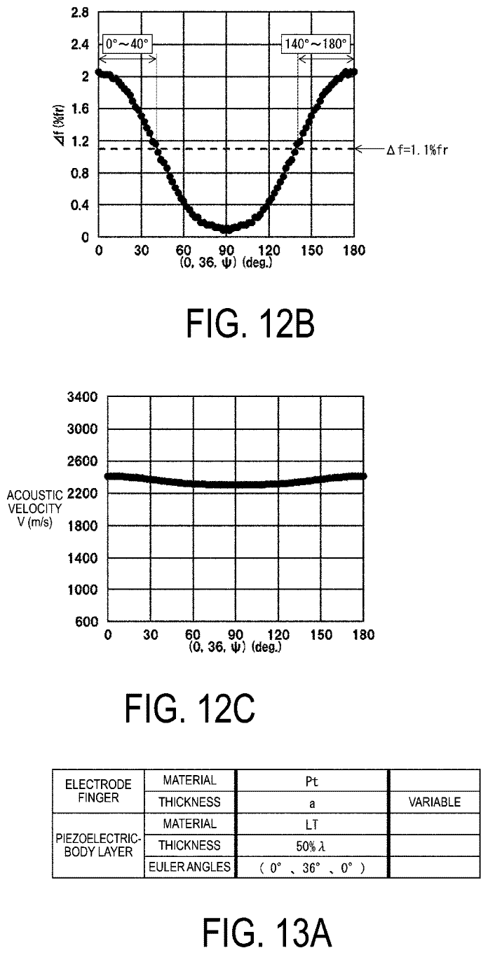

FIG. 12A is a table showing conditions of FEM simulation related to a LT propagation angle in Study Example 2. FIG. 12B is a graph showing FEM simulation results of relationship between a LT propagation angle and a fractional bandwidth Δf in Study Example 2. FIG. 12C is a graph showing FEM simulation results of relationship between a LT propagation angle and an acoustic velocity V in Study Example 2. In the FEM simulation regarding the LT propagation angle in Study Example 2, the Cu electrode thickness was fixed to 20% λ, which is the center point CP in the above-described FEM simulation result. The LT thickness was fixed to 37.5% λ, which is the center point CP in the above-described FEM simulation result, and the LT cut angle was fixed to 36°.

As shown in FIGS. 12A to 12C, it can be seen that the fractional bandwidth Δf was 1.1% fr or more, when the LT propagation angle was in a range from 0° to 40° or a range from 140° to 180°, in other words, when the LT propagation angle was in a range from −40° to 40°. Since the LT propagation angles of 0° and 180° are equivalent to each other, the fitted curve of the plot of the fractional bandwidth Δf shown in FIG. 12B actually has an upwardly convex peak. The local maximum point in the fitted curve was selected as the center point CP. That is, the center point CP of the LT propagation angle was 0°.

### Second Configuration Example

In the acoustic wave device 100 according to a second configuration example of the present embodiment based on the FEM simulation results of Study Example 2 described above, the piezoelectric-body layer 2 includes lithium tantalate (LT) as a main component of the constituent material thereof and has a thickness ranging from 17.5% λ to 90.0% λ. The piezoelectric-body layer 2 has Euler angles (φ, θ, ψ), where φ is in a range from −5° to 5°, θ is in a range from −20° to 80°, and ψ is in a range from −40° to 40°. The IDT electrode 3 includes Cu as a main component of the constituent material thereof and has a thickness ranging from 0.2% λ to 58.0% λ. The range from −5° to 5° for ψ in the Euler angles of the piezoelectric-body layer 2 is defined as tolerance in manufacturing process.

In the acoustic wave device 100 according to the second configuration example of the present embodiment, the piezoelectric-body layer 2 may be the same as that in the first configuration example. The IDT electrode 3 may be made of Cu or may be substantially made of Cu. The IDT electrode 3 may include Cu in an amount of 70 mass % or more or 80 mass % or more. The IDT electrode 3 may include, as constituent materials other than Cu, an optional additive component and inevitable impurities.

In the acoustic wave device 100 according to the second configuration example, the resonator 1 can effectively excite or receive the A0 mode Lamb wave. Using the A0 mode Lamb wave propagating at the acoustic velocity V lower than those of the known SAWs makes it possible to miniaturize the resonator 1. As a result, the acoustic wave device 100 having frequency characteristics including the fractional bandwidth Δf of 1.1% fr or more can be effectively miniaturized. This is also achieved by third to eighth configuration examples described below, and will not be described repeatedly.

### Study Example 3: LT Film/Pt Electrode

In Study Example 3, FEM simulations in which the electrode material was Pt and the piezoelectric-body layer 2 was a LT film were performed.

### Pt Electrode Thickness

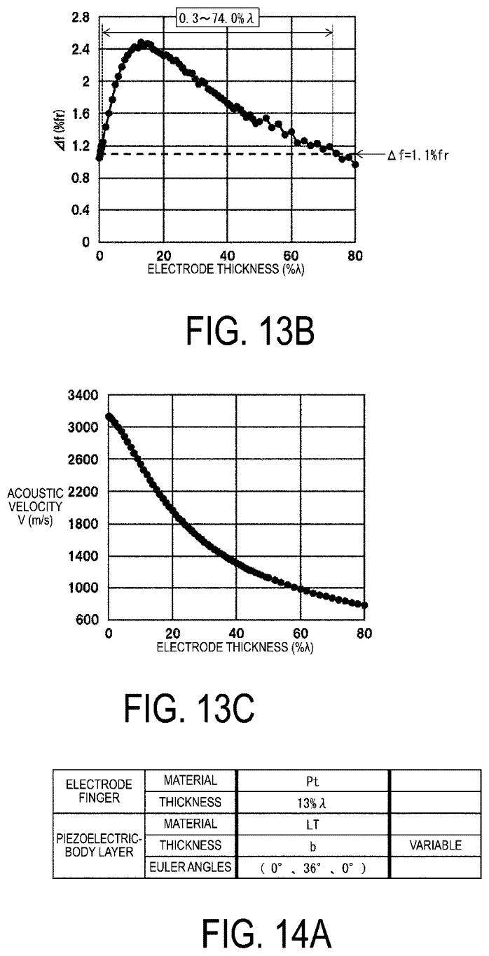

FIG. 13A is a table showing conditions of FEM simulation related to a Pt electrode thickness in Study Example 3. FIG. 13B is a graph showing FEM simulation results of relationship between a Pt electrode thickness and a fractional bandwidth Δf in Study Example 3. FIG. 13C is a graph showing FEM simulation results of relationship between a Pt electrode thickness and an acoustic velocity V in Study Example 3. In the FEM simulation regarding the Pt electrode thickness in Study Example 3, the Euler angles of the piezoelectric-body layer 2 were fixed to general values (0°, 36°, 0°).

As shown in FIGS. 13A to 13C, it can be seen that the fractional bandwidth Δf was 1.1% fr or more, when the Pt electrode thickness was in a range from 0.3% λ to 74.0% λ. As for the relationship between the acoustic velocity V and the Pt electrode thickness, it can be seen that the acoustic velocity V generally tends to decrease with increasing Pt electrode thickness. The local maximum point in a fitted curve of the plot of the fractional bandwidth Δf shown in FIG. 13B was selected as the center point CP. Thus, the center point CP of the Pt electrode thickness in Study Example 3 was 13% λ.

### LT Thickness

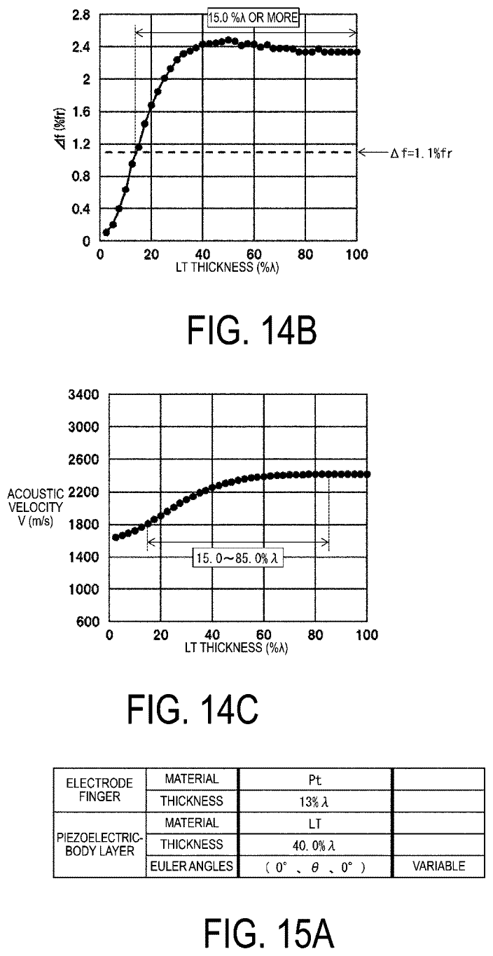

FIG. 14A is a table showing conditions of FEM simulation related to a LT thickness in Study Example 3. FIG. 14B is a graph showing FEM simulation results of relationship between a LT thickness and a fractional bandwidth Δf in Study Example 3. FIG. 14C is a graph showing FEM simulation results of relationship between a LT thickness and an acoustic velocity V in Study Example 3. In the FEM simulation regarding the LT thickness in Study Example 3, the Euler angles of the piezoelectric-body layer 2 were fixed to general values (0°, 36°, 0°), and the Pt electrode thickness was fixed to 13% λ, which is the center point CP in the above-described FEM simulation result.

As shown in FIGS. 14A to 14C, it can be seen that the fractional bandwidth Δf was 1.1% fr or more, when the LT Thickness was in a range of 15.0% λ or more. When the LT thickness was in a range of 15.0% λ or more, the acoustic velocity V increased with increasing the LT thickness, and the acoustic velocity V reached a saturated value when the LT thickness was 85.0% λ. Based on this result, a point at which the fractional bandwidth Δf was relatively large and the acoustic velocity B was relatively low was selected as the center point CP. Thus, the center point CP of the LT thickness in Study Example 3 was 40.0% λ.

### LT Cut Angle

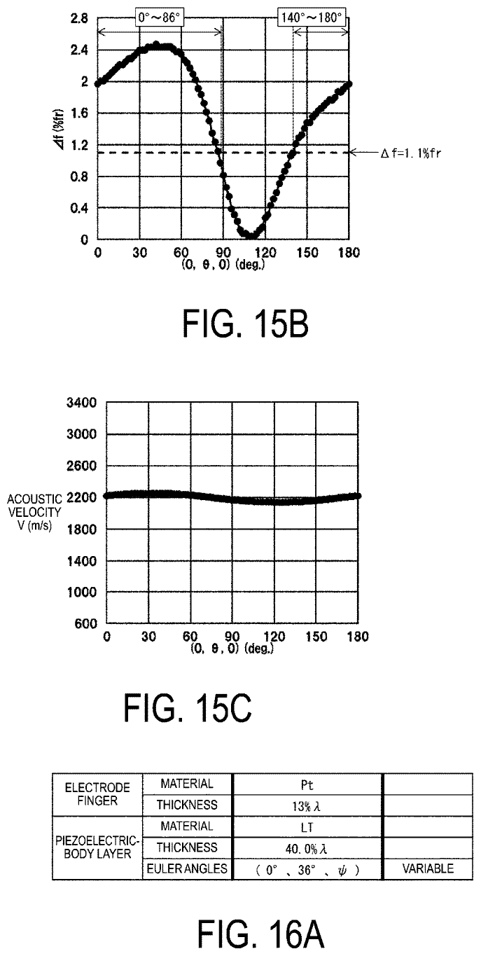

FIG. 15A is a table showing conditions of FEM simulation related to a LT cut angle in Study Example 3. FIG. 15B is a graph showing FEM simulation results of relationship between a LT cut angle and a fractional bandwidth Δf in Study Example 3. FIG. 15C is a graph showing FEM simulation results of relationship between a LT cut angle and an acoustic velocity V in Study Example 3. In the FEM simulation regarding the LT cut angle in Study Example 3, the Pt electrode thickness was fixed to 13% λ, which is the center point CP in the above-described FEM simulation result. The LT thickness was fixed to 40.0% λ, which is the center point CP in the above-described FEM simulation result.

As shown in FIGS. 15A to 15C, it can be seen that the fractional bandwidth Δf was 1.1% fr or more, when the LT cut angle was in a range from 0° to 86° or a range from 140° to 180°, in other words, when the LT cut angle was in a range from −40° to 86°. For the sake of consistency with searches in other FEM simulation, the center point CP of the LT cut angle was set to 36°. As shown in FIG. 15B, it can be seen that the center point CP of the LT cut angle is located near the local maximum point in the fitted curve of the plot of the fractional bandwidth Δf.

### LT Propagation Angle

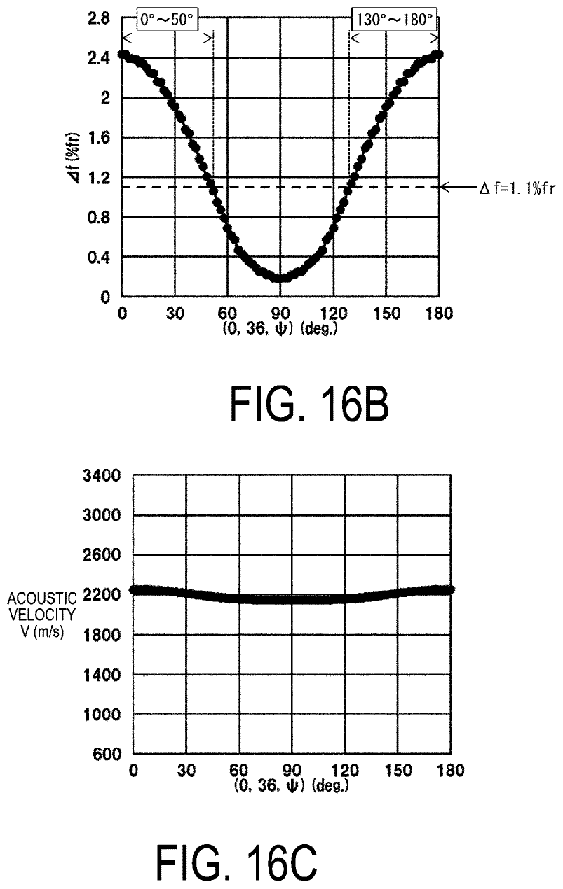

FIG. 16A is a table showing conditions of FEM simulation related to a LT propagation angle in Study Example 3. FIG. 16B is a graph showing FEM simulation results of relationship between a LT propagation angle and a fractional bandwidth Δf in Study Example 3. FIG. 16C is a graph showing FEM simulation results of relationship between a LT propagation angle and an acoustic velocity V in Study Example 3. In the FEM simulation regarding the LT propagation angle in Study Example 3, the Pt electrode thickness was fixed to 13% λ, which is the center point CP in the above-described FEM simulation result. The LT thickness was fixed to 40.0% λ, which is the center point CP in the above-described FEM simulation result, and the LT cut angle was fixed to 36°.

As shown in FIGS. 16A to 16C, it can be seen that the fractional bandwidth Δf was 1.1% fr or more, when the LT propagation angle was in a range from 0° to 50° or a range from 130° to 180°, in other words, when the LT propagation angle was in a range from −50° to 50°. Since the LT propagation angles of 0° and 180° are equivalent to each other, the fitted curve of the plot of the fractional bandwidth Δf shown in FIG. 16B actually has an upwardly convex peak. The local maximum point in the fitted curve was selected as the center point CP. That is, the center point CP of the LT propagation angle was 0°.

### Third Configuration Example

In the acoustic wave device 100 according to a third configuration example of the present embodiment based on the FEM simulation results of Study Example 3 described above, the piezoelectric-body layer 2 includes lithium tantalate (LT) as a main component of the constituent material thereof and has a thickness ranging from 15.0% λ to 85.0% λ. The piezoelectric-body layer 2 has Euler angles (φ, θ, ψ), where φ is in a range from −5° to 5°, θ is in a range from −40° to 86°, and ψ is in a range from −50° to 50°. The IDT electrode 3 includes Pt as a main component of the constituent material thereof and has a thickness ranging from 0.3% λ to 74.0% λ. The range from −5° to 5° for φ in the Euler angles of the piezoelectric-body layer 2 is defined as tolerance in manufacturing process.

In the acoustic wave device 100 according to the third configuration example of the present embodiment, the piezoelectric-body layer 2 may be the same as that in the first configuration example. The IDT electrode 3 may be made of Pt or may be substantially made of Pt. The IDT electrode 3 may include Pt in an amount of 70 mass % or more or 80 mass % or more. The IDT electrode 3 may include, as constituent materials other than Pt, an optional additive component and inevitable impurities.

### Study Example 4: LT Film/Metal Electrode

In Study Examples 1 to 3, the electrode materials were Al, Cu, and Pt, respectively, and the piezoelectric-body layer 2 was an LT film. On the other hand, in Study Example 4, based on the results of Study Examples 1 to 3 described above, studies on the electrode material for making the IDT electrode 3 when the piezoelectric-body layer 2 is an LT film was further conducted.

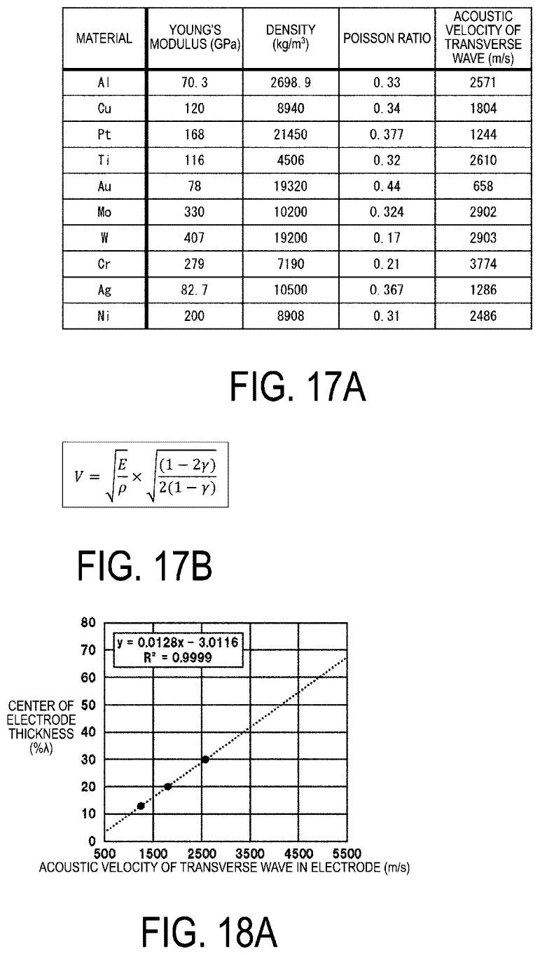

FIG. 17A is a table showing acoustic velocities of a transverse wave in major metal materials. FIG. 17B shows an equation for calculating an acoustic velocity of a transverse wave. In the equation shown in FIG. 17B, V is an acoustic velocity of a transverse wave (m/s), E is a Young's modulus (Pa), p is a density (kg/m³), and γ0 is a Poisson's ratio.

As shown in FIG. 17A, the acoustic velocities of a transverse wave in Al, Cu, and Pt which were used in Study Examples 1 to 3, are 2571 m/s, 1804 m/s, and 1244 m/s, respectively.

In Study Example 1 described above, the center point CP of the Al electrode thickness was 30% λ, an acoustic velocity (an acoustic velocity of an elastic wave) V at the center point CP was about 3000 m/s, and a fractional bandwidth Δf at the center point CP was about 1.6 (see FIGS. 5A to 5C). In Study Example 2 described above, the center point CP of the Cu electrode thickness was 20% λ, an acoustic velocity (an acoustic velocity of an elastic wave) V at the center point CP was about 2500 m/s, and a fractional bandwidth Δf at the center point CP was about 2.1 (see FIGS. 9A to 9C). In Study Example 3 described above, the center point CP of the Pt electrode thickness was 13% λ, an acoustic velocity (an acoustic velocity of an elastic wave) V at the center point CP was about 2300 m/s, and a fractional bandwidth Δf at the center point CP was about 2.5 (see FIGS. 13A to 13C).

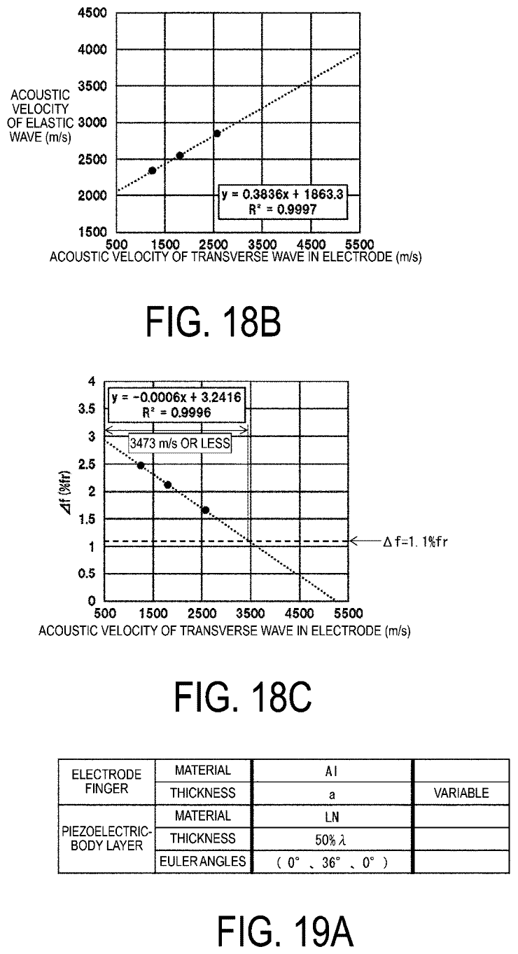

FIG. 18A is a graph showing relationship between the acoustic velocities of a transverse wave in the electrode materials and center points CP of the electrode thicknesses, based on the results of Study Examples 1 to 3. FIG. 18B is a graph showing relationship between the acoustic velocities of a transverse wave in the electrode materials and acoustic velocities (acoustic velocities of an elastic wave) V, based on the results of Study Examples 1 to 3. FIG. 18C is a graph showing relationship between the acoustic velocities of a transverse wave in the electrode materials and fractional bandwidths Δf, based on the results of Study Examples 1 to 3. Each of FIGS. 18A to 18C shows a straight line calculated as a linear functional approximation of plots corresponding to the results of Study Examples 1 to 3, and a coefficient of determination. As shown in FIGS. 18A to 18C, it can be seen that the acoustic velocities of a transverse wave in electrode materials and the acoustic velocities (acoustic velocities of an elastic wave) V have the relationship of a linear function, and the acoustic velocities of a transverse wave in electrode materials and the fractional bandwidths Δf have the relationship of a linear function.

As shown in FIG. 18C, it can be seen that the fractional bandwidth Δf was 1.1% fr or more, when the acoustic velocity of a transverse wave in an electrode material was 3473 m/s or less. In an electrode using an electrode material having a low acoustic velocity of transverse wave, energy is likely to concentrate around the electrode, and as a result, the fractional bandwidth Δf is likely to increase. As shown in FIG. 17A, among the typical metal materials, Au has the slowest acoustic velocity of a transverse wave that was 658 m/s. Based on this, the lower limit of the acoustic velocity of a transverse wave in an electrode material was set to 500 m/s.

### Fourth Configuration Example

In the acoustic wave device 100 according to a fourth configuration example of the present embodiment based on the FEM simulation results of Study Examples 1 to 3 described above and the results of the above-described study, the piezoelectric-body layer 2 includes lithium tantalate as a main component of the constituent material thereof and has a thickness ranging from 15.0% λ to 90.0% λ. The piezoelectric-body layer 2 has Euler angles (φ, θ, ψ), where φ is in a range from −5° to 5°, θ is in a range from −40° to 86°, and ψ is in a range from −50° to 50°. The IDT electrode 3 includes, as a main component of the constituent material thereof, a metal having an acoustic velocity of a transverse wave ranging from 500 m/s to 3473 m/s, and has a thickness ranging from 0.2% λ to 74.0% λ.

In the acoustic wave device 100 according to another example of the fourth configuration example of the present embodiment based on the FEM simulation results of Study Examples 1 to 3 described above and the results of the above-described study, the piezoelectric-body layer 2 includes lithium tantalate as a main component of the constituent material thereof and has a thickness ranging from 20.0% λ to 85.0% λ. The piezoelectric-body layer 2 has Euler angles (φ, θ, ψ), where φ is in a range from −5° to 5°, θ is in a range from 8° to 74°, and ψ is in a range from −26° to 26°. The IDT electrode 3 includes, as a main component of the constituent material thereof, a metal having an acoustic velocity of a transverse wave ranging from 500 m/s to 3473 m/s, and has a thickness ranging from 0.6% λ to 50.0% λ.

In the acoustic wave device 100 according to the fourth configuration example of the present embodiment or the other example of the fourth configuration example, the piezoelectric-body layer 2 may be the same as that in the first configuration example. The IDT electrode 3 may be made of a metal having an acoustic velocity of a transverse wave in a range from 500 m/s to 3473 m/s (hereinafter referred to as a “specific metal M1”), may be substantially made of the specific metal M1, or may include the specific metal M1 as a main component of the constituent material thereof.

The main component of the constituent material for the IDT electrode 3 may be specified in accordance with the electrode structure of the IDT electrode 3. For example, when the electrode has a layered structure, a material having the highest concentration in the thickest layer among a plurality of layers included in the layered structure can be considered as the main component. The average of the acoustic velocities of a transverse wave, in the materials of the plurality of layers included in the layered structure may be considered as the acoustic velocity of a transverse wave of the constituent material of the IDT electrode 3, and in this case, for example, the average may be in a range from 500 m/s to 3473 m/s. When the electrode has a layered structure, the acoustic velocity can be calculated as, for example, a volume average velocity.

The electrode in the IDT electrode 3 may include an alloy. When the electrode includes an alloy, the material having the highest concentration in the composition of the alloy may be considered as the main component. The concentration in the composition of the alloy can be measured using, for example, energy dispersive X-ray spectroscopy (EDX) or wavelength-dispersive X-ray spectroscopy (WDX). The acoustic velocity of a transverse wave in the constituent material of the IDT electrode 3 calculated based on the density, Young's modulus, and Poisson's ratio of the alloy may be in a range from 500 m/s to 3473 m/s, for example. The Poisson's ratios of various alloys are, for example, 0.3.

### Study Example 5: LN Film/Al Electrode

Next, in Study Example 5, FEM simulations in which the electrode material was Al and the piezoelectric-body layer 2 was a LN film were performed.

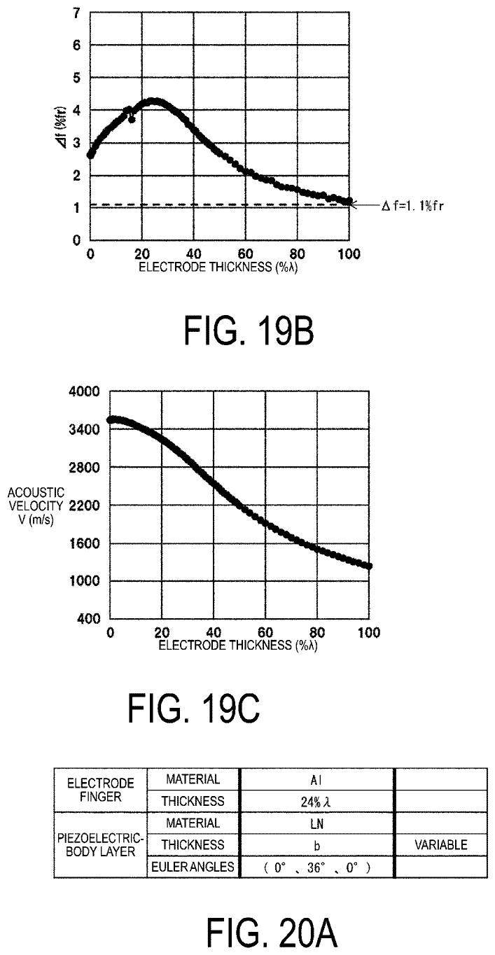

Al Electrode Thickness FIG. 19A is a table showing conditions of FEM simulation related to an Al electrode thickness in Study Example 5. FIG. 19B is a graph showing FEM simulation results of relationship between an Al electrode thickness and a fractional bandwidth Δf in Study Example 5. FIG. 19C is a graph showing FEM simulation results of relationship between an Al electrode thickness and an acoustic velocity V in Study Example 5. In the FEM simulation regarding the Al electrode thickness in Study Example 5, the Euler angles of the piezoelectric-body layer 2 were fixed to general values (0°, 36°, 0°).

As shown in FIGS. 19A to 19C, it can be seen that the fractional bandwidth Δf was 1.1% fr or more, when the Al electrode thickness was in a range of 100% λ or less. An Al electrode thickness greater than 100% λ is impractical, and a too thin Al electrode thickness is also impractical. The range of the Al electrode thickness can be defined as a range from 0.05% λ to 100.0% λ. The range of the Al electrode thickness may be defined as a range from 0.05% λ to 50.0% λ, because an Al electrode thickness falling within this range results in a fractional bandwidth Δf equal to or greater than the fractional bandwidth Δf when the Al electrode thickness is 0.05% λ.

The local maximum point in a fitted curve of the plot of the fractional bandwidth Δf shown in FIG. 19B was selected as the center point CP. Thus, the center point CP of the Al electrode thickness in Study Example 5 was 24% λ.

### LN Thickness

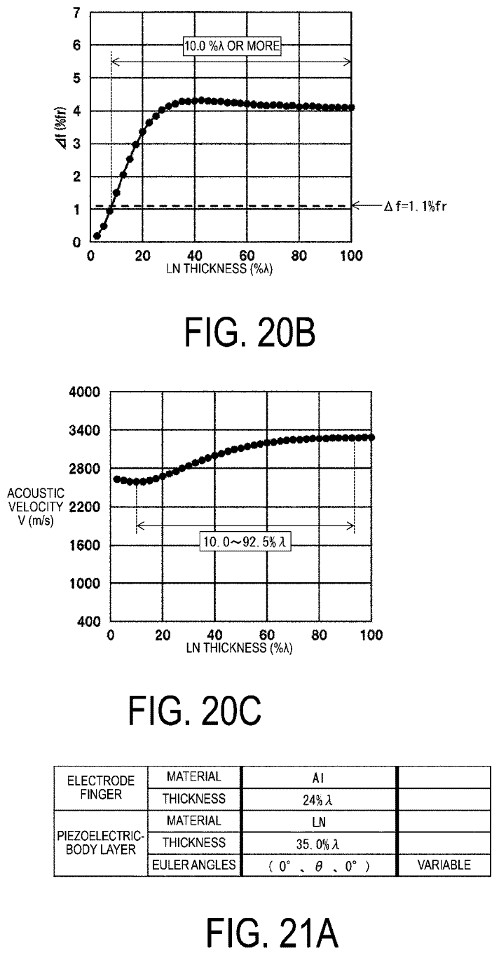

FIG. 20A is a table showing conditions of FEM simulation related to a LN thickness in Study Example 5. FIG. 20B is a graph showing FEM simulation results of relationship between a LN thickness and a fractional bandwidth Δf in Study Example 5. FIG. 20C is a graph showing FEM simulation results of relationship between a LN thickness and an acoustic velocity V in Study Example 5. In the FEM simulation regarding the LN thickness in Study Example 5, the Euler angles of the piezoelectric-body layer 2 were fixed to general values (0°, 36°, 0°), and the Al electrode thickness was fixed to 24% λ, which is the center point CP in the above-described FEM simulation result.

As shown in FIGS. 20A to 20C, it can be seen that the fractional bandwidth Δf was 1.1% fr or more, when the LN Thickness was in a range of 10.0% λ or more. When the LN thickness was in a range of 10.0% λ or more, the acoustic velocity V increased with increasing the LN thickness, and the acoustic velocity V reached a saturated value when the LN thickness was 92.5% λ. Based on this result, a point at which the fractional bandwidth Δf was relatively large and the acoustic velocity B was relatively low was selected as the center point CP. Thus, the center point CP of the LN thickness in Study Example 5 was 35.0% λ.

### LN Cut Angle

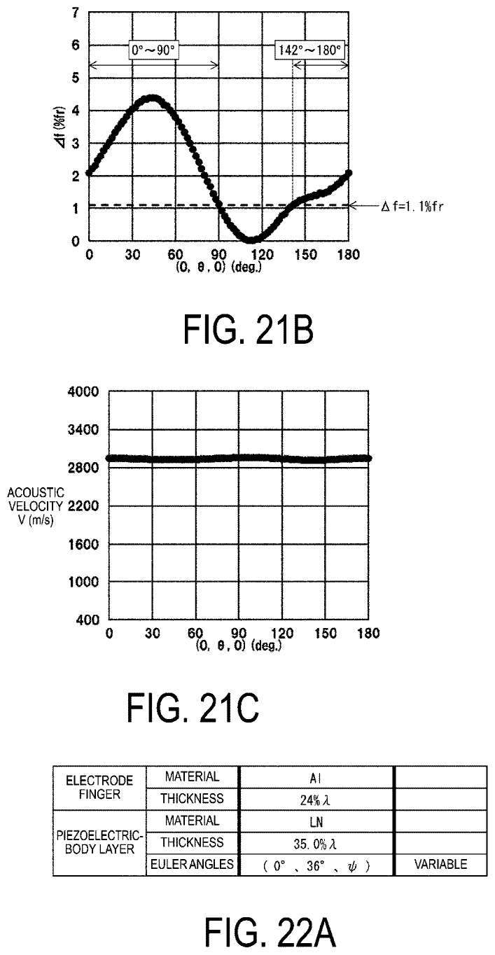

FIG. 21A is a table showing conditions of FEM simulation related to a LN cut angle in Study Example 5. FIG. 21B is a graph showing FEM simulation results of relationship between a LN cut angle and a fractional bandwidth Δf in Study Example 5. FIG. 21C is a graph showing FEM simulation results of relationship between a LN cut angle and an acoustic velocity V in Study Example 5. In the FEM simulation regarding the LN cut angle in Study Example 5, the Al electrode thickness was fixed to 24% λ, which is the center point CP in the above-described FEM simulation result, and the LN thickness was fixed to 35.0% λ, which is the center point CP in the above-described FEM simulation result.

As shown in FIGS. 21A to 21C, it can be seen that the fractional bandwidth Δf was 1.1% fr or more, when the LN cut angle was in a range from 0° to 90° or a range from 142° to 180°, in other words, when the LN cut angle was in a range from −38° to 90°. For the sake of consistency with searches in other FEM simulation, the center point CP of the LN cut angle was set to 36°. As shown in FIG. 21B, it can be seen that the center point CP of the LN cut angle is located near the local maximum point in the fitted curve of the plot of the fractional bandwidth Δf.

### LN Propagation Angle

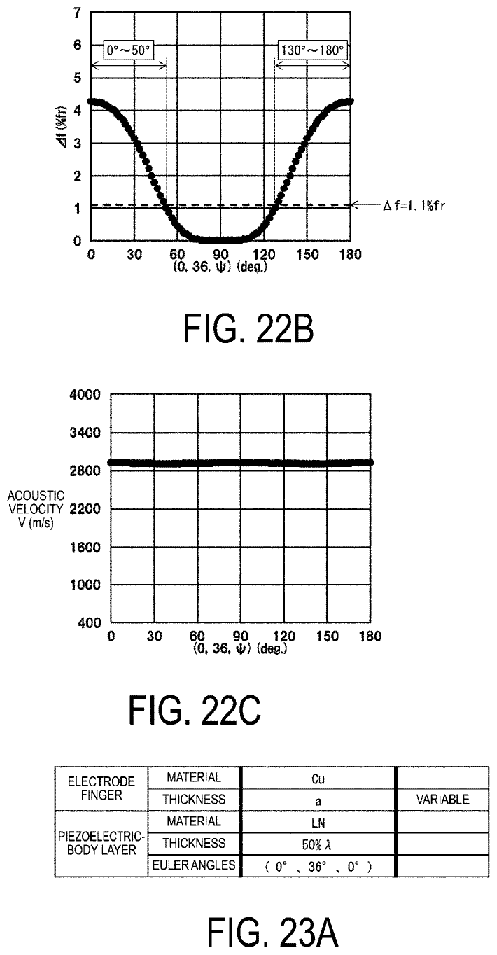

FIG. 22A is a table showing conditions of FEM simulation related to a LN propagation angle in Study Example 5. FIG. 22B is a graph showing FEM simulation results of relationship between a LN propagation angle and a fractional bandwidth Δf in Study Example 5. FIG. 22C is a graph showing FEM simulation results of relationship between a LN propagation angle and an acoustic velocity V in Study Example 5. In the FEM simulation regarding the LN propagation angle in Study Example 5, the Al electrode thickness was fixed to 24% λ, which is the center point CP in the above-described FEM simulation result. The LN thickness was fixed to 35.0% λ, which is the center point CP in the above-described FEM simulation result, and the LN cut angle was fixed to 36°.

As shown in FIGS. 22A to 22C, it can be seen that the fractional bandwidth Δf was 1.1% fr or more, when the LN propagation angle was in a range from 0° to 50° or a range from 130° to 180°, in other words, when the LN propagation angle was in a range from −50° to 50°. Since the LN propagation angles of 0° and 180° are equivalent to each other, the fitted curve of the plot of the fractional bandwidth Δf shown in FIG. 22B actually has an upwardly convex peak. The local maximum point in the fitted curve was selected as the center point CP. That is, the center point CP of the LN propagation angle was 0°.

### Fifth Configuration Example

In the acoustic wave device 100 according to a fifth configuration example of the present embodiment based on the FEM simulation results of Study Example 5 described above, the piezoelectric-body layer 2 includes lithium niobate as a main component of the constituent material thereof and has a thickness ranging from 10.0% λ to 92.5% λ. The piezoelectric-body layer 2 has Euler angles (φ, θ, ψ), where φ is in a range from −5° to 5°, θ is in a range from −38° to 90°, and ψ is in a range from −50° to 50°. The IDT electrode 3 includes Al as a main component of the constituent material thereof and has a thickness ranging from 0.05% λ to 100.0% λ.

In the acoustic wave device 100 according to the fifth configuration example of the present embodiment, the piezoelectric-body layer 2 may be made of LN or substantially made of LN. The piezoelectric-body layer 2 may include LN in an amount of 70 mass % or more or 80 mass % or more. The piezoelectric-body layer 2 may include, as constituent materials other than LN, an optional additive component and inevitable impurities.

The IDT electrode 3 may be made of Al or may be substantially made of Al. The IDT electrode 3 may include Al in an amount of 70 mass % or more or 80 mass % or more. The IDT electrode 3 may include, as constituent materials other than Al, an optional additive component and inevitable impurities.

### Study Example 6: LN Film/Cu Electrode

In Study Example 6, FEM simulations in which the electrode material was Cu and the piezoelectric-body layer 2 was a LN film were performed.

### Cu Electrode Thickness

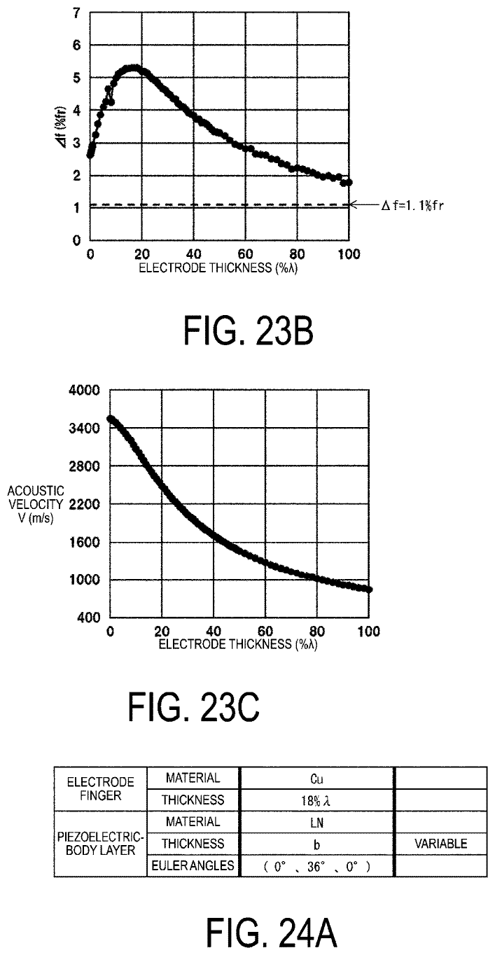

FIG. 23A is a table showing conditions of FEM simulation related to a Cu electrode thickness in Study Example 6. FIG. 23B is a graph showing FEM simulation results of relationship between a Cu electrode thickness and a fractional bandwidth Δf in Study Example 6. FIG. 23C is a graph showing FEM simulation results of relationship between a Cu electrode thickness and an acoustic velocity V in Study Example 6. In the FEM simulation regarding the Cu electrode thickness in Study Example 6, the Euler angles of the piezoelectric-body layer 2 were fixed to general values (0°, 36°, 0°).

As shown in FIGS. 23A to 23C, it can be seen that the fractional bandwidth Δf was 1.1% fr or more, when the Cu electrode thickness was in a range of 100% λ or less. A Cu electrode thickness greater than 100% λ is impractical, and a too thin Cu electrode thickness is also impractical. The range of the Cu electrode thickness can be defined as a range from 0.05% λ to 100.0% λ. The range of the Cu electrode thickness may be defined as a range from 0.05% λ to 66.0% λ, because a Cu electrode thickness falling within this range results in a fractional bandwidth Δf equal to or greater than the fractional bandwidth Δf when the Cu electrode thickness is 0.05% λ.

The local maximum point in a fitted curve of the plot of the fractional bandwidth Δf shown in FIG. 23B was selected as the center point CP. Thus, the center point CP of the Cu electrode thickness in Study Example 6 was 18% λ.

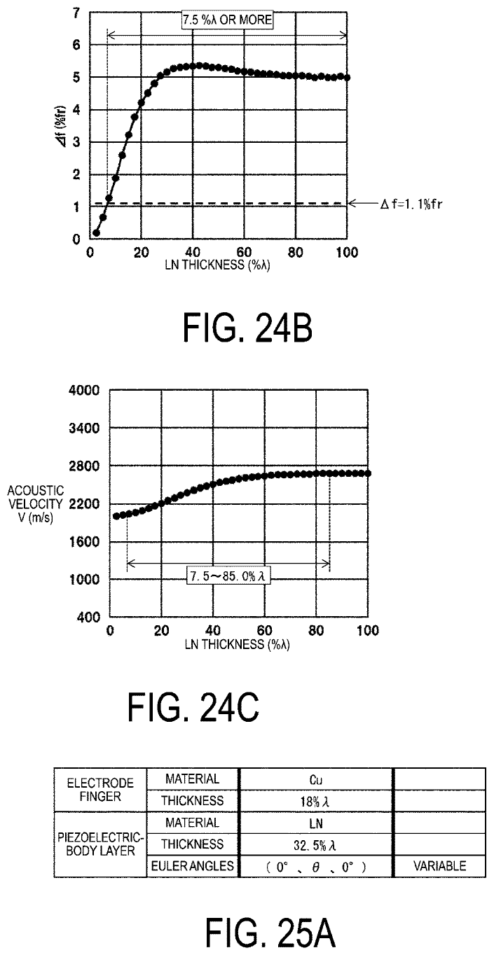

LN Thickness FIG. 24A is a table showing conditions of FEM simulation related to a LN thickness in Study Example 6. FIG. 24B is a graph showing FEM simulation results of relationship between a LN thickness and a fractional bandwidth Δf in Study Example 6. FIG. 24C is a graph showing FEM simulation results of relationship between a LN thickness and an acoustic velocity V in Study Example 6. In the FEM simulation regarding the LN thickness in Study Example 6, the Euler angles of the piezoelectric-body layer 2 were fixed to general values (0°, 36°, 0°), and the Cu electrode thickness was fixed to 18% λ, which is the center point CP in the above-described FEM simulation result.

As shown in FIGS. 24A to 24C, it can be seen that the fractional bandwidth Δf was 1.1% fr or more, when the LN Thickness was in a range of 7.5% λ or more. When the LN thickness was in a range of 7.5% λ or more, the acoustic velocity V increased with increasing the LN thickness, and the acoustic velocity V reached a saturated value when the LN thickness was 85.0% λ. Based on this result, a point at which the fractional bandwidth Δf was relatively large and the acoustic velocity B was relatively low was selected as the center point CP. Thus, the center point CP of the LN thickness in Study Example 6 was 32.5% λ.

### LN Cut Angle

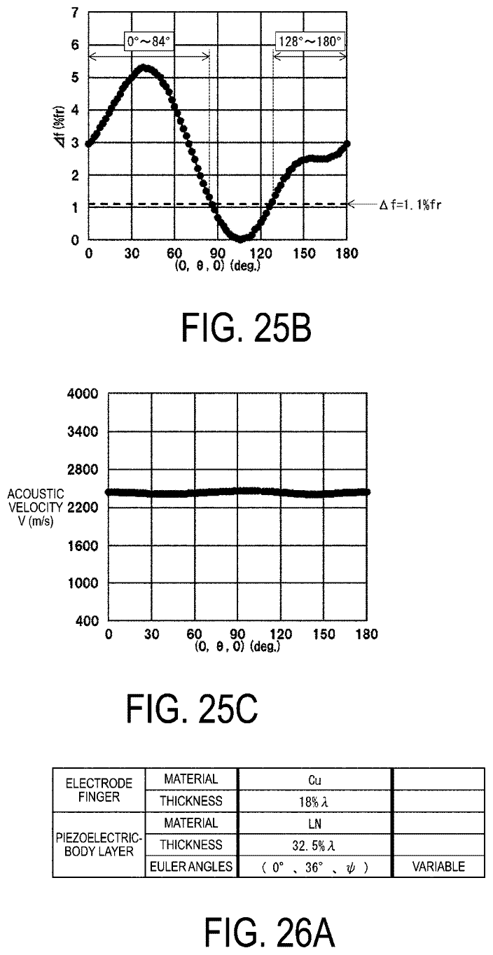

FIG. 25A is a table showing conditions of FEM simulation related to a LN cut angle in Study Example 6. FIG. 25B is a graph showing FEM simulation results of relationship between a LN cut angle and a fractional bandwidth Δf in Study Example 6. FIG. 25C is a graph showing FEM simulation results of relationship between a LN cut angle and an acoustic velocity V in Study Example 6. In the FEM simulation regarding the LN cut angle in Study Example 6, the Cu electrode thickness was fixed to 18% λ, which is the center point CP in the above-described FEM simulation result, and the LN thickness was fixed to 32.5% λ, which is the center point CP in the above-described FEM simulation result.

As shown in FIGS. 25A to 25C, it can be seen that the fractional bandwidth Δf was 1.1% fr or more, when the LN cut angle was in a range from 0° to 84° or a range from 128° to 180°, in other words, when the LN cut angle was in a range from −52° to 84°. For the sake of consistency with searches in other FEM simulation, the center point CP of the LN cut angle was set to 36°. As shown in FIG. 25B, it can be seen that the center point CP of the LN cut angle is located near the local maximum point in the fitted curve of the plot of the fractional bandwidth Δf.

### LN Propagation Angle

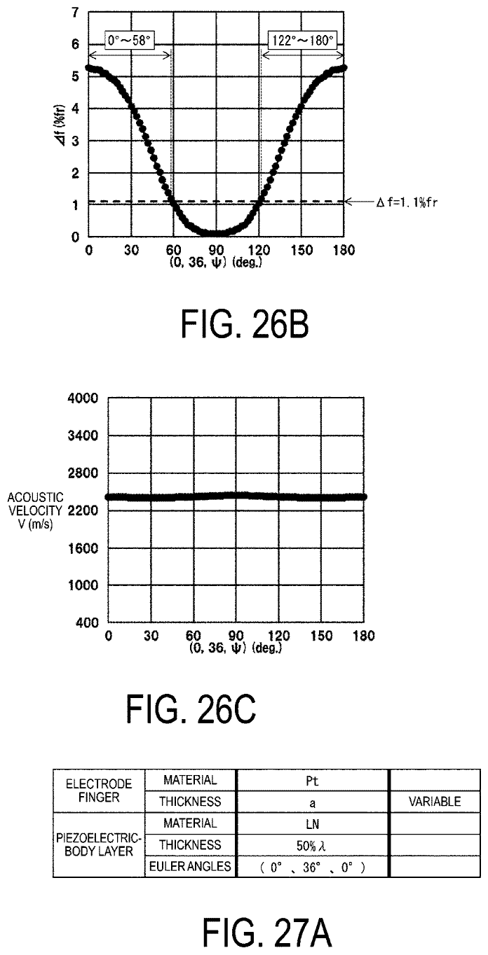

FIG. 26A is a table showing conditions of FEM simulation related to a LN propagation angle in Study Example 6. FIG. 26B is a graph showing FEM simulation results of relationship between a LN propagation angle and a fractional bandwidth Δf in Study Example 6. FIG. 26C is a graph showing FEM simulation results of relationship between a LN propagation angle and an acoustic velocity V in Study Example 6. In the FEM simulation regarding the LN propagation angle in Study Example 6, the Cu electrode thickness was fixed to 18% λ, which is the center point CP in the above-described FEM simulation result. The LN thickness was fixed to 32.5% λ, which is the center point CP in the above-described FEM simulation result, and the LN cut angle was fixed to 36°.

As shown in FIGS. 26A to 26C, it can be seen that the fractional bandwidth Δf was 1.1% fr or more, when the LN propagation angle was in a range from 0° to 58° or a range from 122° to 180°, in other words, when the LN propagation angle was in a range from −58° to 58°. Since the LN propagation angles of 0° and 180° are equivalent to each other, the fitted curve of the plot of the fractional bandwidth Δf shown in FIG. 26B actually has an upwardly convex peak. The local maximum point in the fitted curve was selected as the center point CP. That is, the center point CP of the LN propagation angle was 0°.

### Sixth Configuration Example

In the acoustic wave device 100 according to a sixth configuration example of the present embodiment based on the FEM simulation results described above, the piezoelectric-body layer 2 includes lithium niobate as a main component of the constituent material thereof and has a thickness ranging from 7.5% λ to 85.0% λ. The piezoelectric-body layer 2 has Euler angles (φ, θ, ψ), where φ is in a range from −5 5°, θ is in a range from −52° to 84°, and ψ is in a range from −58° to 58°. The IDT electrode 3 includes Cu as a main component of the constituent material thereof and has a thickness ranging from 0.05% λ to 100.0% λ.

In the acoustic wave device 100 according to the sixth configuration example of the present embodiment, the piezoelectric-body layer 2 may be the same as that in the fifth configuration example. The IDT electrode 3 may be made of Cu or may be substantially made of Cu. The IDT electrode 3 may include Cu in an amount of 70 mass % or more or 80 mass % or more. The IDT electrode 3 may include, as constituent materials other than Cu, an optional additive component and inevitable impurities.

### Study Example 7: LN Film/Pt Electrode

In Study Example 7, FEM simulations in which the electrode material was Pt and the piezoelectric-body layer 2 was a LN film were performed.

### Pt Electrode Thickness

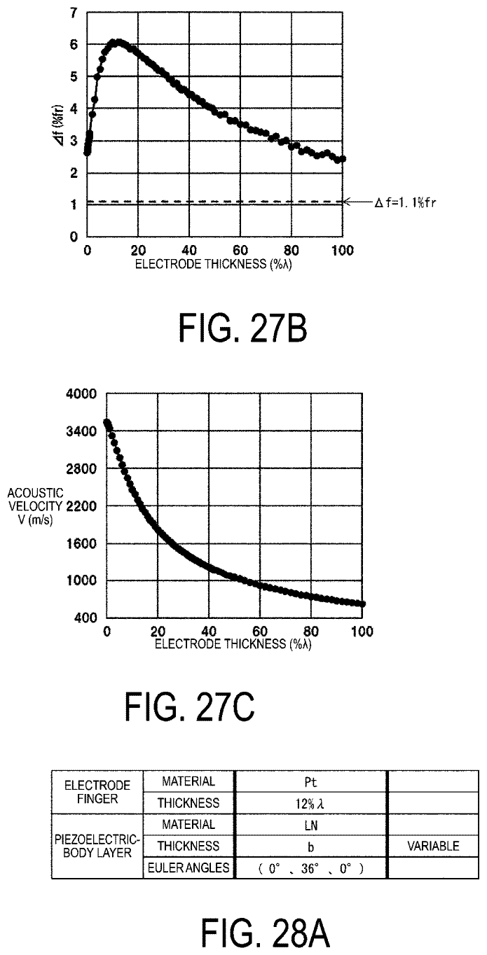

FIG. 27A is a table showing conditions of FEM simulation related to a Pt electrode thickness in Study Example 7. FIG. 27B is a graph showing FEM simulation results of relationship between a Pt electrode thickness and a fractional bandwidth Δf in Study Example 7. FIG. 27C is a graph showing FEM simulation results of relationship between a Pt electrode thickness and an acoustic velocity V in Study Example 7. In the FEM simulation regarding the Pt electrode thickness in Study Example 7, the Euler angles of the piezoelectric-body layer 2 were fixed to general values (0°, 36°, 0°).

As shown in FIGS. 27A to 27C, it can be seen that the fractional bandwidth Δf was 1.1% fr or more, when the Pt electrode thickness was in a range of 100% λor less. A Pt electrode thickness greater than 100% λ is impractical, and a too thin Pt electrode thickness is also impractical. The range of the Pt electrode thickness can be defined as a range from 0.05% λ to 100.0% λ. The range of the Pt electrode thickness may be defined as a range from 0.05% λ to 86.0% λ, because a Pt electrode thickness falling within this range results in a fractional bandwidth Δf equal to or greater than the fractional bandwidth Δf when the Pt electrode thickness is 0.05% λ.

The local maximum point in a fitted curve of the plot of the fractional bandwidth Δf shown in FIG. 27B was selected as the center point CP. Thus, the center point CP of the Pt electrode thickness in Study Example 7 was 12% λ.

### LN Thickness

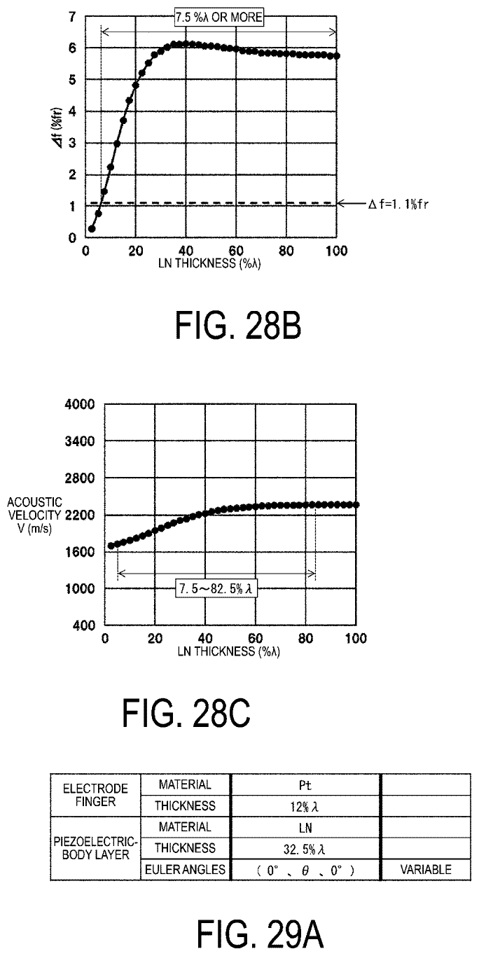

FIG. 28A is a table showing conditions of FEM simulation related to a LN thickness in Study Example 7. FIG. 28B is a graph showing FEM simulation results of relationship between a LN thickness and a fractional bandwidth Δf in Study Example 7. FIG. 28C is a graph showing FEM simulation results of relationship between a LN thickness and an acoustic velocity V in Study Example 7. In the FEM simulation regarding the LN thickness in Study Example 7, the Euler angles of the piezoelectric-body layer 2 were fixed to general values (0°, 36°, 0°), and the Pt electrode thickness was fixed to 12% λ, which is the center point CP in the above-described FEM simulation result.

As shown in FIGS. 28A to 28C, it can be seen that the fractional bandwidth Δf was 1.1% fr or more, when the LN Thickness was in a range of 7.5% λ or more. When the LN thickness was in a range of 7.5% λ or more, the acoustic velocity V increased with increasing the LN thickness, and the acoustic velocity V reached a saturated value when the LN thickness was 82.5% λ. Based on this result, a point at which the fractional bandwidth Δf was relatively large and the acoustic velocity B was relatively low was selected as the center point CP. Thus, the center point CP of the LN thickness in Study Example 7 was 32.5% λ.

### LN Cut Angle

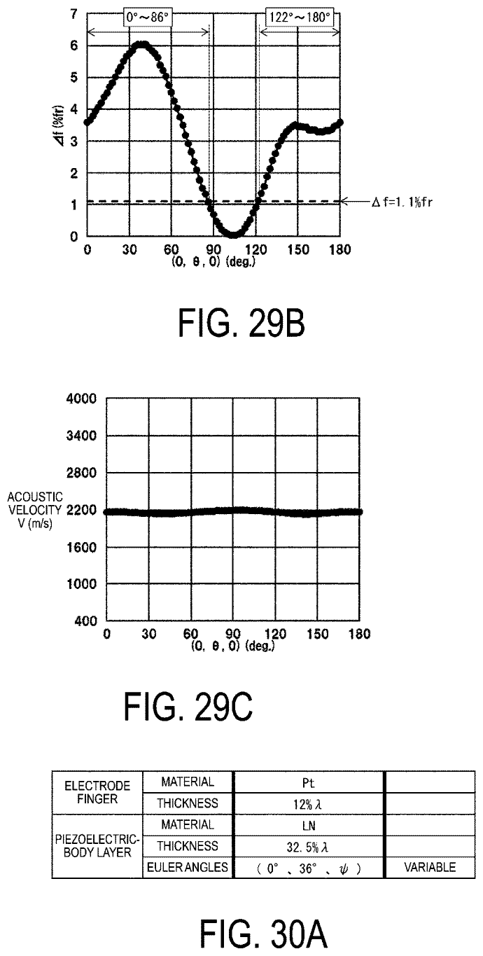

FIG. 29A is a table showing conditions of FEM simulation related to a LN cut angle in Study Example 7. FIG. 29B is a graph showing FEM simulation results of relationship between a LN cut angle and a fractional bandwidth Δf in Study Example 7. FIG. 29C is a graph showing FEM simulation results of relationship between a LN cut angle and an acoustic velocity V in Study Example 7. In the FEM simulation regarding the LN cut angle in Study Example 7, the Pt electrode thickness was fixed to 12% λ, which is the center point CP in the above-described FEM simulation result. The LN thickness was fixed to 32.5% λ, which is the center point CP in the above-described FEM simulation result.

As shown in FIGS. 29A to 29C, it can be seen that the fractional bandwidth Δf was 1.1% fr or more, when the LN cut angle was in a range from 0° to 86° or a range from 122° to 180°, in other words, when the LN cut angle was in a range from −58° to 86°. For the sake of consistency with searches in other FEM simulation, the center point CP of the LN cut angle was set to 36°. As shown in FIG. 29B, it can be seen that the center point CP of the LN cut angle is located near the local maximum point in the fitted curve of the plot of the fractional bandwidth Δf.

### LN Propagation Angle

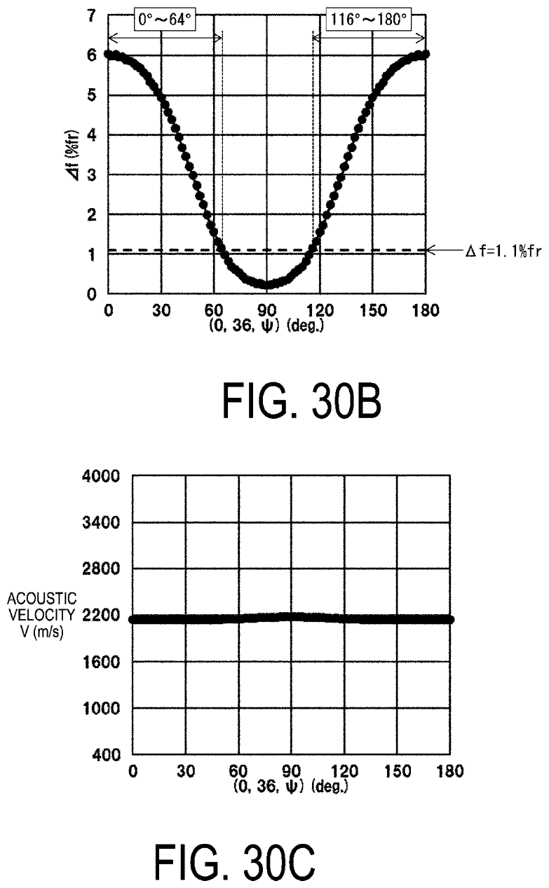

FIG. 30A is a table showing conditions of FEM simulation related to a LN propagation angle in Study Example 7. FIG. 30B is a graph showing FEM simulation results of relationship between a LN propagation angle and a fractional bandwidth Δf in Study Example 7. FIG. 30C is a graph showing FEM simulation results of relationship between a LN propagation angle and an acoustic velocity V in Study Example 7. In the FEM simulation regarding the LN propagation angle in Study Example 7, the Pt electrode thickness was fixed to 12% λ, which is the center point CP in the above-described FEM simulation result. The LN thickness was fixed to 32.5% λ, which is the center point CP in the above-described FEM simulation result, and the LN cut angle was fixed to 36°.

As shown in FIGS. 30A to 30C, it can be seen that the fractional bandwidth Δf was 1.1% fr or more, when the LN propagation angle was in a range from 0° to 64° or a range from 116° to 180°, in other words, when the LN propagation angle was in a range from −64° to 64°. Since the LN propagation angles of 0° and 180° are equivalent to each other, the fitted curve of the plot of the fractional bandwidth Δf shown in FIG. 30B actually has an upwardly convex peak. The local maximum point in the fitted curve was selected as the center point CP. That is, the center point CP of the LN propagation angle was 0°.

### Seventh Configuration Example

In the acoustic wave device 100 according to a seventh configuration example of the present embodiment based on the FEM simulation results described above, the piezoelectric-body layer 2 includes lithium niobate as a main component of the constituent material thereof and has a thickness ranging from 7.5% λ to 82.5% λ. The piezoelectric-body layer 2 has Euler angles (φ, θ, ψ), where φ0 is in a range from −5° to 5°, θ is in a range from −58° to 86°, and ψ is in a range from −64° to 64°. The IDT electrode 3 includes Pt as a main component of the constituent material thereof and has a thickness ranging from 0.05% λ to 100.0% λ.

In the acoustic wave device 100 according to the seventh configuration example of the present embodiment, the piezoelectric-body layer 2 may be the same as that in the fifth configuration example. The IDT electrode 3 may be made of Pt or may be substantially made of Pt. The IDT electrode 3 may include Pt in an amount of 70 mass % or more or 80 mass % or more. The IDT electrode 3 may include, as constituent materials other than Pt, an optional additive component and inevitable impurities. cl Study Example 8: LN Film/Metal Electrode

In Study Examples 5 to 7, the electrode materials were Al, Cu, and Pt, respectively, and the piezoelectric-body layer 2 was an LN film. On the other hand, in Study Example 8, based on the results of Study Examples 5 to 7 described above, studies on the electrode material for making the IDT electrode 3 when the piezoelectric-body layer 2 is an LN film was further conducted.

The description with reference to FIGS. 17A and 17B in Study Example 4 is common matters with Study Example 8, and thus a repeated description is omitted.

In Study Example 5 described above, the center point CP of the Al electrode thickness was 24% λ, an acoustic velocity (an acoustic velocity of an elastic wave) V at the center point CP was about 3100 m/s, and a fractional bandwidth Δf at the center point CP was about 4.2 (see FIGS. 19A to 19C). In Study Example 6 described above, the center point CP of the Cu electrode thickness was 18% λ, an acoustic velocity (an acoustic velocity of an elastic wave) V at the center point CP was about 2600 m/s, and a fractional bandwidth Δf at the center point CP was about 5.3 (see FIGS. 23A to 23C). In Study Example 7 described above, the center point CP of the Pt electrode thickness was 12% λ, an acoustic velocity (an acoustic velocity of an elastic wave) V at the center point CP was about 2300 m/s, and a fractional bandwidth Δf at the center point CP was about 6.0 (see FIGS. 27A to 27C).

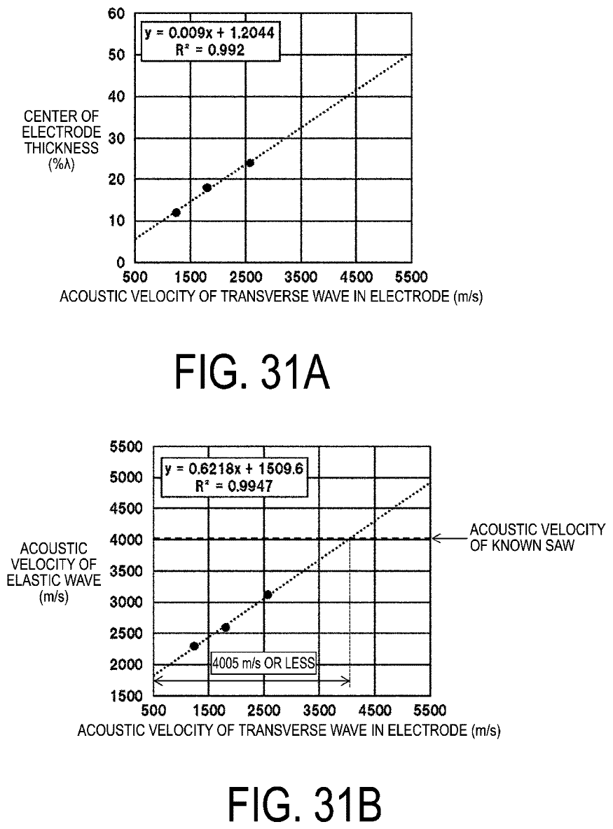

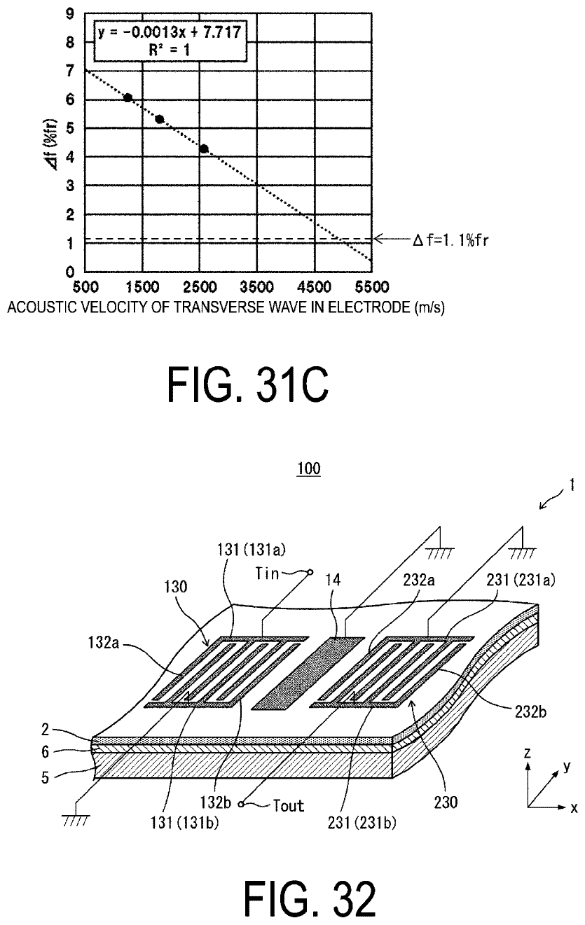

FIG. 31A is a graph showing relationship between the acoustic velocities of a transverse wave in the electrode materials and center points CP of the electrode thicknesses, based on the results of Study Examples 5 to 7. FIG. 31B is a graph showing relationship between the acoustic velocities of a transverse wave in the electrode materials and acoustic velocities (acoustic velocities of an elastic wave) V, based on the results of Study Examples 5 to 7. FIG. 31C is a graph showing relationship between the acoustic velocities of a transverse wave in the electrode materials and fractional bandwidths Δf, based on the results of Study Examples 5 to 7. Each of FIGS. 31A to 31C shows a straight line calculated as a linear functional approximation of plots corresponding to the results of Study Examples 5 to 7, and a coefficient of determination. As shown in FIGS. 31A to 31C, it can be seen that the acoustic velocities of a transverse wave in electrode materials and the acoustic velocities (acoustic velocities of an elastic wave) V have the relationship of a linear function, and the acoustic velocities of a transverse wave in electrode materials and the fractional bandwidths Δf have the relationship of a linear function.

As shown in FIG. 31C, it can be seen that the fractional bandwidth Δf was 1.1% fr or more, when the acoustic velocity of a transverse wave in an electrode material was about 5000 m/s or less. Here, the acoustic velocity of the known SAWs is about 4000 m/s. Examples of known SAWs include Rayleigh waves and leaky waves. The acoustic velocity of the leaky wave propagating through the LT film is about 4000 m/s. Thus, as shown in FIGS. 31B, 4005 m/s is selected as the upper limit of the acoustic velocity of a transverse wave in an electrode material, because an acoustic velocity of a transverse wave falling within this range results in an acoustic velocity (acoustic velocity of an elastic wave) V lower than those of the known SAWs. The lower limit of the acoustic velocity of a transverse wave in an electrode material was set to 500 m/s, as in Study Example 4 described above.

### Eighth Configuration Example

In the acoustic wave device 100 according to an eighth configuration example of the present embodiment based on the FEM simulation results of Study Examples 5 to 7 described above and the results of the above-described study, the piezoelectric-body layer 2 includes lithium niobate as a main component of the constituent material thereof and has a thickness ranging from 7.5% λ to 92.5% λ. The piezoelectric-body layer 2 has Euler angles (φ, θ, ψ), where o is in a range from −5° to 5°, θ is in a range from −58° to 90°, and w is in a range from −64° to 64°. The IDT electrode 3 includes, as a main component of the constituent material thereof, a metal having an acoustic velocity of a transverse wave ranging from 500 m/s to 4005 m/s, and has a thickness ranging from 0.05% λ to 100.0% λ.

In the acoustic wave device 100 according to another example of the eighth configuration example of the present embodiment based on the FEM simulation results of Study Examples 5 to 7 described above and the results of the above-described study, the piezoelectric-body layer 2 includes lithium niobate as a main component of the constituent material thereof and has a thickness ranging from 10.0% λ to 82.5% λ. The piezoelectric-body layer 2 has Euler angles (φ, θ, ψ), where φ is in a range from −5° to 5°, θ is in a range from −38° to 84°, and ψ is in a range from −50° to 50°. The IDT electrode 3 includes, as a main component of the constituent material thereof, a metal having an acoustic velocity of a transverse wave ranging from 500 m/s to 4005 m/s, and has a thickness ranging from 0.05% λ to 100.0% λ.

In the acoustic wave device 100 according to the eighth configuration example of the present embodiment or the other example of the eighth configuration example, the piezoelectric-body layer 2 may be the same as that in the fifth configuration example. The IDT electrode 3 may be made of a metal having an acoustic velocity of a transverse wave in a range from 500 m/s to 4005 m/s (hereinafter referred to as a “specific metal M2”), may be substantially made of the specific metal M2, or may include the specific metal M2 as a main component of the constituent material thereof. The relationship between the constituent material for the IDT electrode 3 and the range of acoustic velocity of a transverse wave is the same as that described with respect to the above-described fourth configuration example, and thus repeated description is omitted.

### Other Structural Examples

FIG. 32 is a perspective view of another structural example of the acoustic wave device 100 according to the present embodiment. As described above, as long as the acoustic wave device 100 according to the present embodiment is configured to excite an AO mode Lamb wave, the specific shape of the IDT electrode 3 is not particularly limited. For example, as illustrated in FIG. 32, the acoustic wave device 100 may include a transversal type resonator 1.

In the example illustrated in FIG. 32, the resonator 1 may include a first IDT electrode 130 (an input-side IDT electrode) and a second IDT electrode 230 (an output-side IDT electrode) arranged in the X direction. The first IDT electrode 130 may include two bus bars 131 (a first bus bar 131a and a second bus bar 131b) facing each other in the y direction. The second IDT electrode 230 may include two bus bars 231 (a first bus bar 231a and a second bus bar 231b) facing each other in the y direction.

For example, the input terminal Tin may be connected to the first bus bar 131a of the first IDT electrode 130, and the output terminal Tout may be connected to the second bus bar 231b of the second IDT electrode 230. The second bus bar 131b of the first IDT electrode 130 and the first bus bar 231a of the second IDT electrode 230 may be connected to ground terminals, respectively.

In the example illustrated in FIG. 32, the acoustic wave device 100 may include a third electrode 14 in a propagation path between the first IDT electrode 130 and the second IDT electrode 230. The third electrode 14 may be, for example, an aluminum electrode film, and has a function of improving propagation efficiency of signals (A0 mode Lamb wave) from the first IDT electrode 130 to the second IDT electrode 230. The third electrode 14 may be or may not be connected to a ground terminal. In the acoustic wave device 100, the third electrode 14 may not be provided.

In the acoustic wave device 100, each of the first IDT electrode 130 and the second IDT electrode 230 may have a shape and a component ratio that are the same as and/or similar to those of the IDT electrode 3 described above. A known configuration can be employed for the third electrode 14.

### Other Configuration 1

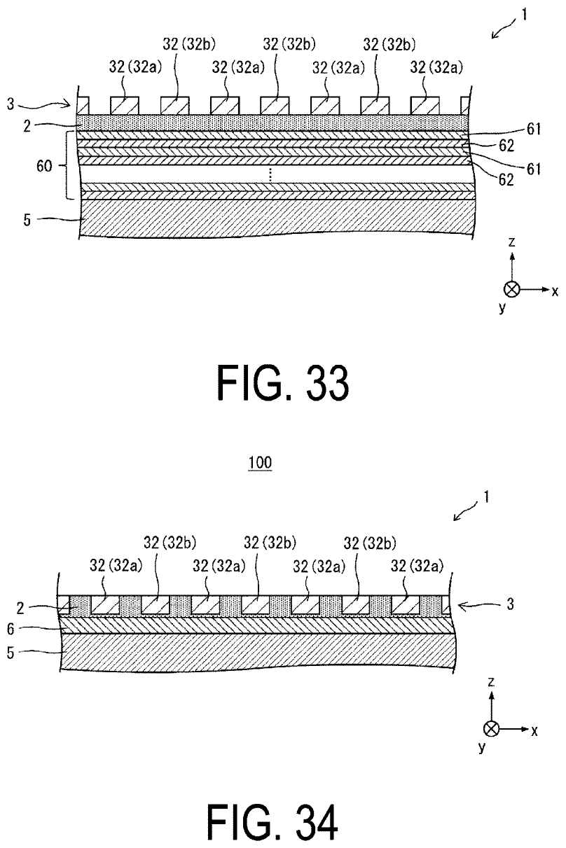

FIG. 33 is a cross-sectional view of another configuration example of the acoustic wave device 100 according to the present embodiment. In the acoustic wave device 100 of the example illustrated in FIG. 33, the resonator 1 may include an acoustic reflection film between the support substrate 5 and the piezoelectric-body layer 2. A specific structure of the acoustic reflection film is not particularly limited. For example, the acoustic wave device 100 may include a reflective multilayer film 60 between the support substrate 5 and the piezoelectric-body layer 2.

The reflective multilayer film 60 may include first layers 61 and second layers 62, which are alternately layered. The constituent material for the first layer 61 may have a lower acoustic impedance than the constituent material for the second layer 62. For example, the first layer 61 may include, as a main component of the constituent material thereof, silicon dioxide (SiO₂). For example, the second layer 62 may include, as a main component of the constituent material thereof, hafnium oxide (HfO₂). The second layer 62 may include, as a main component of the constituent material thereof, any of tantalum pentoxide (Ta₂O₅), zirconium dioxide (ZrO₂), titanium oxide (TiO₂), and magnesium oxide (MgO). The reflective multilayer film 60 may include at least one first layer 61 and at least one second layer 62. In the reflective multilayer film 60, a layer in contact with the piezoelectric-body layer 2 is the first layer 61. On the other hand, in the reflective multilayer film 60, the layer closest to the support substrate 5 may be the first layer 61 or may be the second layer 62. For example, in the reflective multilayer film 60, the sum of the number of the first layers 61 and the number of the second layers 62 may be in a range from 3 to 12.

### Other Configuration 2

FIG. 34 is a cross-sectional view of another variation of the acoustic wave device 100 according to the present embodiment. In the example illustrated in FIG. 34, in the resonator 1 included in the acoustic wave device 100, the IDT electrode 3 may be at least partly embedded in the piezoelectric-body layer 2.

In the example illustrated in FIG. 34, top surfaces of the electrode fingers 32 and a top surface of the piezoelectric-body layer 2 are at the same height (are flush with each other), but this is not essential. For example, the IDT electrode 3 may be embedded in the piezoelectric-body layer 2 such that the top surfaces of the electrode fingers 32 protrude or are recessed from the top surface of the piezoelectric-body layer 2. This allows effective reduction of spurious components.

### Other Configuration 3

The resonance frequency of the acoustic wave device 100 may be, for example, in a range from 700 MHz to 900 MHz. When the cross-sectional thicknesses (expressed in % λ) of the piezoelectric-body layer 2 and the IDT electrode 3 is constant, the acoustic velocity V of the A0 mode Lamb wave is also constant. In this case, according to V=fλ. (V: constant), the resonance frequency can be adjusted by changing λ (i.e., the electrode finger pitch p). In other words, λ is set such that a desired resonance frequency is achieved, and the cross-sectional thicknesses (expressed in % λ) of the piezoelectric-body layer 2 and the IDT electrode 3 are calculated based on the set λ. The resonator 1 including the piezoelectric-body layer 2 and the IDT electrode 3 having the calculated thicknesses may be manufactured.

### Communication Apparatus

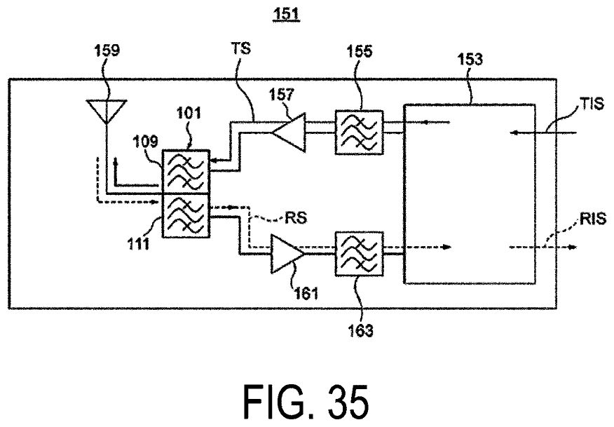

FIG. 35 is a diagram illustrating a simplified configuration of a communication apparatus 151. The communication apparatus 151 is an example of application of the acoustic wave device 100 according to an aspect of the present disclosure, and performs radio communication using radio waves. The communication apparatus 151 may include one duplexer 101 as a transmission filter 109 and another duplexer 101 as a reception filter 111. Each of the two duplexers 101 may include the acoustic wave device 100 according to an aspect of the present disclosure. As such, the communication apparatus 151 may include the acoustic wave device 100 according to an aspect of the present disclosure.

In the communication apparatus 151, a radio frequency-integrated circuit (RF-IC) 153 may convert, into a transmission signal TS, a transmission information signal TIS including information to be transmitted, by modulating TIS and increasing the frequency of TIS (converting TIS to a high-frequency signal having a frequency of a carrier wave). A band-pass filter 155 may remove, from the TS, unnecessary components other than a transmission passband. Subsequently, the TS from which unnecessary components have been removed may be amplified by an amplifier 157 and sent to the transmission filter 109.

The transmission filter 109 may remove, from the received transmission signal TS, unnecessary components other than the transmission passband. The transmission filter 109 may output the TS from which unnecessary components have been removed, to an antenna 159 via an antenna terminal. The antenna 159 may convert the TS, which is an electrical signal input to the antenna 159, into a radio wave as a radio signal, and transmit the radio wave to the outside of the communication apparatus 151.

The antenna 159 may receive a radio wave from the outside, convert the radio wave into a received signal RS being an electrical signal, and send the RS to the reception filter 111 via the antenna terminal. The reception filter 111 may remove, from the received RS, unnecessary components other than a reception passband. The reception filter 111 may output the received signal RS from which unnecessary components have been removed, to an amplifier 161. The amplifier 161 may amplify the output RS. A band-pass filter 163 may remove, from the amplified RS, unnecessary components other than a reception passband. The RF-IC 153 may convert, into a reception information signal RIS, the RS from which unnecessary components have been removed, by decreasing the frequency of the RS and demodulating the RS.

The TIS and RIS may be low-frequency signals (baseband signals) including appropriate information. For example, the TIS and RIS may be analog audio signals or digitized audio signals. The passband of the radio signal may be appropriately set or may conform to various known standards.

### Supplementary Notes

The invention according to the present disclosure has been described above based on the various drawings and examples. However, the invention according to the present disclosure is not limited to the above-described embodiments and examples. That is, the invention according to the present disclosure can be variously changed within the scope illustrated in the present disclosure, and embodiments obtained by appropriately combining the technical means disclosed in different embodiments and examples are also included in the technical scope of the invention according to the present disclosure. In other words, note that those skilled in the art can easily make various variations or modifications based on the present disclosure. Note that such variations or modifications are included within the scope of the present disclosure.

### Reference Signs

1 Resonator
2 Piezoelectric-body layer
3 IDT electrode
31 Bus bar
32 Electrode finger
4 Reflector
5 Support substrate
6 Intermediate layer
100 Acoustic wave device

1. An acoustic wave device configured to excite an asymmetric zero-order mode Lamb wave, the acoustic wave device comprising:
a support substrate;
a piezoelectric-body layer in direct or indirect contact with the support substrate; and
an IDT electrode located on the piezoelectric-body layer.

2. The acoustic wave device according to claim 1, wherein
the asymmetric zero-order mode Lamb wave has a wavelength λ defined as a length twice as long as a pitch of a plurality of electrode fingers comprised in the IDT electrode,
the piezoelectric-body layer
comprises lithium tantalate as a main component of a constituent material of the piezoelectric-body layer,
has a thickness ranging from 20.0% λ to 87.5% λ, and
has Euler angles (φ, θ, ψ), where φ ranges from −5° to 5°, θ ranges from 8° to 74°, and ψ ranges from −26° to 26°, and
the IDT electrode
comprises Al as a main component of a constituent material of the IDT electrode, and
has a thickness ranging from 0.6% λ to 50.0% λ.

3. The acoustic wave device according to claim 1, wherein
the asymmetric zero-order mode Lamb wave has a wavelength λ defined as a length twice as long as a pitch of a plurality of electrode fingers comprised in the IDT electrode,
the piezoelectric-body layer
comprises lithium tantalate as a main component of a constituent material of the piezoelectric-body layer,
has a thickness ranging from 17.5% λ to 90.0% λ, and
has Euler angles (φ, θ, ψ), where φ ranges from −5° to 5°, θ ranges from −20° to 80°, and ψ ranges from −40° to 40°, and
the IDT electrode
comprises Cu as a main component of a constituent material of the IDT electrode, and
has a thickness ranging from 0.2% λ to 58.0% λ.

4. The acoustic wave device according to claim 1, wherein
the asymmetric zero-order mode Lamb wave has a wavelength A defined as a length twice as long as a pitch of a plurality of electrode fingers comprised in the IDT electrode,
the piezoelectric-body layer
comprises lithium tantalate as a main component of a constituent material of the piezoelectric-body layer,
has a thickness ranging from 15.0% λ to 85.0% λ, and
has Euler angles (φ, θ, ψ), where φ ranges from −5° to 5°, θ ranges from −40° to 86°, and w ranges from −50° to 50°, and
the IDT electrode
comprises Pt as a main component of a constituent material of the IDT electrode, and
has a thickness ranging from 0.3% λ to 74.0% λ .

5. The acoustic wave device according to claim 1, wherein
the asymmetric zero-order mode Lamb wave has a wavelength λ defined as a length twice as long as a pitch of a plurality of electrode fingers comprised in the IDT electrode,
the piezoelectric-body layer
comprises lithium tantalate as a main component of a constituent material of the piezoelectric-body layer,
has a thickness ranging from 15.0% λ to 90.0% λ, and
has Euler angles (φ, θ, ψ), where θ ranges from −5° to 5°, θ ranges from −40° to 86°, and ψ ranges from −50° to 50°, and
the IDT electrode
comprises, as a main component of a constituent material of the IDT electrode, a metal having an acoustic velocity of a transverse wave ranging from 500 m/s to 3473 m/s, and
has a thickness ranging from 0.2% λ to 74.0% λ.

6. The acoustic wave device according to claim 1, wherein
the asymmetric zero-order mode Lamb wave has a wavelength λ defined as a length twice as long as a pitch of a plurality of electrode fingers comprised in the IDT electrode,
the piezoelectric-body layer
comprises lithium tantalate as a main component of a constituent material of the piezoelectric-body layer,
has a thickness ranging from 20.0% λ to 85.0% λ, and has Euler angles (φ, θ, ψ), where φ ranges from −5° to 5°, θ ranges from 8° to 74°, and ψ ranges from −26° to 26°, and
the IDT electrode
comprises, as a main component of a constituent material of the IDT electrode, a metal having an acoustic velocity of a transverse wave ranging from 500 m/s to 3473 m/s, and
has a thickness ranging from 0.6% λ to 50.0% λ.

7. The acoustic wave device according to claim 1, wherein
the asymmetric zero-order mode Lamb wave has a wavelength λ defined as a length twice as long as a pitch of a plurality of electrode fingers comprised in the IDT electrode,
the piezoelectric-body layer
comprises lithium niobate as a main component of a constituent material of the piezoelectric-body layer,
has a thickness ranging from 10.0% λ to 92.5% λ, and
has Euler angles (φ, θ, ψ), where φ ranges from −5° to 5°, θ ranges from −38° to 90°, and ψ ranges from −50° to 50°, and
the IDT electrode
comprises Al as a main component of a constituent material of the IDT electrode, and
has a thickness ranging from 0.05% λ to 100.0% λ.

8. The acoustic wave device according to claim 1, wherein
the asymmetric zero-order mode Lamb wave has a wavelength λ defined as a length twice as long as a pitch of a plurality of electrode fingers comprised in the IDT electrode,
the piezoelectric-body layer
comprises lithium niobate as a main component of a constituent material of the piezoelectric-body layer,
has a thickness ranging from 7.5% λ to 85.0% λ, and
has Euler angles (φ, θ, ψ), where φ ranges from −5° to 5°, θ ranges from −52° to 84°, and ψ ranges from −58° to 58°, and
the IDT electrode
comprises Cu as a main component of a constituent material of the IDT electrode, and
has a thickness ranging from 0.05% λ to 100.0% λ.

9. The acoustic wave device according to claim 1, wherein
the asymmetric zero-order mode Lamb wave has a wavelength λ defined as a length twice as long as a pitch of a plurality of electrode fingers comprised in the IDT electrode,
the piezoelectric-body layer
comprises lithium niobate as a main component of a constituent material of the piezoelectric-body layer,
has a thickness ranging from 7.5% λ to 82.5% λ, and
has Euler angles (φ, θ, ψ), where φ ranges from −5° to 5°, θ ranges from −58° to 86°, and ψ ranges from −64° to 64°, and
the IDT electrode
comprises Pt as a main component of a constituent material of the IDT electrode, and
has a thickness ranging from 0.05% λ to 100.0% λ.

10. The acoustic wave device according to claim 1, wherein
the asymmetric zero-order mode Lamb wave has a wavelength λ defined as a length twice as long as a pitch of a plurality of electrode fingers comprised in the IDT electrode,
the piezoelectric-body layer
comprises lithium niobate as a main component of a constituent material of the piezoelectric-body layer,
has a thickness ranging from 7.5% λ to 92.5% λ, and
has Euler angles (φ, θ, ψ), where φ ranges from −5° to 5°, θ ranges from −58° to 90°, and ψ ranges from −64° to 64°, and
the IDT electrode
comprises, as a main component of a constituent material of the IDT electrode, a metal having an acoustic velocity of a transverse wave ranging from 500 m/s to 4005 m/s, and
has a thickness ranging from 0.05% λ to 100.0% λ.

11. The acoustic wave device according to claim 1, wherein the asymmetric zero-order mode Lamb wave has a wavelength λ defined as a length twice as long as a pitch of a plurality of electrode fingers comprised in the IDT electrode,
the piezoelectric-body layer
comprises lithium niobate as a main component of a constituent material of the piezoelectric-body layer,
has a thickness ranging from 10.0% λ to 82.5% λ, and
has Euler angles (φ, θ, ψ), where φ ranges from −5° to 5°, θ ranges from −38° to 84°, and ψ ranges from −50° to 50°, and the IDT electrode
comprises, as a main component of a constituent material of the IDT electrode, a metal having an acoustic velocity of a transverse wave ranging from 500 m/s to 4005 m/s, and
has a thickness ranging from 0.05% λ to 100.0% λ.

12. The acoustic wave device according to claim 1, further comprising an intermediate layer between the support substrate and the piezoelectric-body layer.

13. The acoustic wave device according to claim 1, further comprising an acoustic reflection film between the support substrate and the piezoelectric-body layer.

14. The acoustic wave device according to claim 1, wherein the acoustic wave device has a fractional bandwidth of 1.1% or more.

15. The acoustic wave device according to claim 1, wherein the IDT electrode is at least in part embedded in the piezoelectric-body layer.

16. A communication apparatus comprising the acoustic wave device according to claim 1.
